(19) United States
(12) Patent Application Publication
(10) Pub. No.: US 2026/0344078 A1
(43) Pub. Date: Oct. 29, 2026

(54) PHOTODETECTOR

(71) Applicant: SONY SEMICONDUCTOR SOLUTIONS CORPORATION, Kanagawa (JP)

(72) Inventor: Sozo YOKOGAWA, Kanagawa (JP)

(73) Assignee: SONY SEMICONDUCTOR SOLUTIONS CORPORATION, Kanagawa (JP)

(21) Appl. No.: 19/117,880

(22) PCT Filed: Oct. 6, 2023
(86) PCT No.: PCT/JP2023/036586

§ 371 Date: Apr. 2, 2025

(30) Foreign Application Priority Data
Oct. 18, 2022 (JP) 2022-167104

(51) Int. Cl. H10F 39/00; H10F 39/18

(52) U.S. Cl. CPC H10F 39/8063; H10F 39/182; H10F 39/8053

(57) ABSTRACT

A photodetector includes a wavelength separation structure including materials having different refractive indices. The materials are planarly and discretely provided for each of first pixels and second pixels on a first surface of a semiconductor substrate. The wavelength separation structure separates incident light on the first pixel into a first wavelength component and a wavelength component other than the first wavelength component and selectively guides the first wavelength component to the first pixel and separates incident light on the second pixel into a second wavelength component and a wavelength component other than the second wavelength component and selectively guides the second wavelength component to the second pixel.

### CROSS REFERENCE TO RELATED APPLICATIONS

This application claims the benefit of Japanese Priority Patent Application JP 2022-167104 filed on Oct. 18, 2022, the entire contents of which are incorporated herein by reference.

### TECHNICAL FIELD

The present disclosure relates to a photodetector having a wavelength separation structure.

### BACKGROUND ART

For example, PTL 1 discloses an image sensor having improved light efficiency by scattering or diffracting light by a nanopost structure to spatially perform wavelength separation.

### CITATION LIST

### Patent Literature

PTL 1: Japanese Unexamined Patent Application Publication No. 2021-069119

### SUMMARY

### Technical Problem

Incidentally, in a photodetector, an improvement in color balance is desired.

It is desirable to provide a photodetector that makes it possible to improve sensitivity and improve color balance.

A first photodetector according to an embodiment of the present disclosure includes: a semiconductor substrate having a first surface and a second surface that are opposed to each other, and including a plurality of first pixels and a plurality of second pixels arranged in a matrix, the plurality of first pixels and the plurality of second pixels that selectively photoelectrically convert wavelengths different from each other; a wavelength separation structure including media having refractive indices different from each other, the media planarly and discretely provided for each of the first pixels and the second pixels on side of the first surface, the wavelength separation structure that separates incident light on the first pixel into a first wavelength component and a wavelength component other than the first wavelength component and selectively guides the first wavelength component to the first pixel, and separates incident light on the second pixel into a second wavelength component and a wavelength component other than the second wavelength component and selectively guides the second wavelength component to the second pixel; and an opening adjustment structure that is provided on side of the first surface, and causes an effective pixel opening size of one pixel having relatively low light sensitivity of the first pixel and the second pixel to be larger than an effective pixel opening size of the other pixel.

A second photodetector according to an embodiment of the present disclosure includes: a semiconductor substrate having a first surface and a second surface that are opposed to each other, and including a plurality of first pixels and a plurality of second pixels arranged in a matrix, the plurality of first pixels and the plurality of second pixels that selectively photoelectrically convert wavelengths different from each other; a wavelength separation structure including media having refractive indices different from each other, the media planarly and discretely provided for each of the first pixels and the second pixels on side of the first surface, the wavelength separation structure that separates incident light on the first pixel into a first wavelength component and a wavelength component other than the first wavelength component and selectively guides the first wavelength component to the first pixel, and separates incident light on the second pixel into a second wavelength component and a wavelength component other than the second wavelength component and selectively guides the second wavelength component to the second pixel; and a light-condensing element provided, on side of the first surface, for a pixel having relatively low light sensitivity of the first pixel and the second pixel.

A third photodetector according to an embodiment of the present disclosure includes: a semiconductor substrate having a first surface and a second surface that are opposed to each other, and including a plurality of first pixels and a plurality of second pixels arranged in a matrix, the plurality of first pixels and the plurality of second pixels that selectively photoelectrically convert wavelengths different from each other; a wavelength separation structure including media having refractive indices different from each other, the media planarly and discretely provided for each of the first pixels and the second pixels on side of the first surface, the wavelength separation structure that separates incident light on the first pixel into a first wavelength component and a wavelength component other than the first wavelength component and selectively guides the first wavelength component to the first pixel, and separates incident light on the second pixel into a second wavelength component and a wavelength component other than the second wavelength component and selectively guides the second wavelength component to the second pixel; and a color filter layer provided between the first surface and the wavelength separation structure, and including a frame body and a color filter, the frame body provided at a boundary between the first pixel and the second pixel adjacent to each other and having an opening for each of the first pixel and the second pixel, each of the openings being filled with the color filter, the color filter that allows a wavelength to selectively pass therethrough, and the wavelength that is to be photoelectrically converted in each of the first pixel and the second pixel, in which a size of the opening for a pixel having relatively low light sensitivity is larger than a size of the opening for another pixel.

In the first photodetector according to the embodiment of the present disclosure, the wavelength separation structure and the opening adjustment structure are provided on side of the first surface serving as a light incident surface of the semiconductor substrate in which the plurality of first pixels and second pixels is arranged in a matrix. The first pixels and the second pixels selectively photoelectrically convert wavelengths different from each other. The wavelength separation structure includes the media that have refractive indices different from each other and are planarly and discretely provided for each of the first pixels and the second pixels. The wavelength separation structure separates incident light on the first pixel into the first wavelength component and the wavelength component other than the first wavelength component and selectively guides the first wavelength component to the first pixel and separates incident light on the second pixel into the second wavelength component and the wavelength component other than the second wavelength component and selectively guides the second wavelength component to the second pixel. The opening adjustment structure is provided on side of the first surface and causes the effective pixel opening size of one pixel having relatively low light sensitivity of the first pixel and the second pixel to be larger than the effective pixel opening size of the other pixel. In the second photodetector according to the embodiment of the present disclosure, the light-condensing element is provided as the opening adjustment structure for a pixel having relatively low light sensitivity of the first pixel and the second pixel. In the third photodetector according to the embodiment of the present disclosure, the color filter layer including the frame body and the color filter is provided as the opening adjustment structure between the first surface and the wavelength separation structure. The frame body is provided at the boundary between the first pixel and the second pixel adjacent to each other and has an opening for each of the first pixel and the second pixel. Each of the openings is filled with the color filter. The color filter allows a wavelength to selectively pass therethrough. The wavelength is to be photoelectrically converted in each of the first pixel and the second pixel. The color filter layer causes the size of the opening for a pixel having relatively low light sensitivity to be larger than the size of the opening for another pixel. Accordingly, quantum efficiency in the pixel having relatively low light sensitivity is improved.

### BRIEF DESCRIPTION OF DRAWINGS

FIG. 1 is a schematic cross-sectional view of an example of a configuration of a photodetector according to a first embodiment of the present disclosure.

FIG. 2 is a block diagram illustrating an entire configuration of the photodetector illustrated in FIG. 1.

FIG. 3 is an equivalent circuit diagram of a unit pixel illustrated in FIG. 1.

FIG. 4 is a schematic view of an example of a planar layout of the photodetector illustrated in FIG. 1.

FIG. 5 is a schematic perspective view of the photodetector having the planar layout illustrated in FIG. 4.

FIG. 6 is a schematic cross-sectional view of a photodetector as a reference example 1.

FIG. 7 is a schematic cross-sectional view of a photodetector as a reference example 2.

FIG. 8 is a characteristic diagram illustrating quantum efficiencies of R, G, and B in the photodetector illustrated in FIG. 6.

FIG. 9 is a characteristic diagram illustrating quantum efficiencies of R, G, and B in the photodetector illustrated in FIG. 7.

FIG. 10 is a characteristic diagram illustrating quantum efficiencies of R, G, and B in the photodetector illustrated in FIG. 1.

FIG. 11 is a schematic cross-sectional view of an example of a configuration of a photodetector according to a modification example 1 of the present disclosure.

FIG. 12 is a schematic cross-sectional view of an example of a configuration of a photodetector according to a modification example 2 of the present disclosure.

FIG. 13 is a schematic cross-sectional view of an example of a configuration of a photodetector according to a modification example 3 of the present disclosure.

FIG. 14 is a schematic cross-sectional view of another example of the configuration of the photodetector according to modification example 3 of the present disclosure.

FIG. 15 is a schematic cross-sectional view of another example of the configuration of the photodetector according to modification example 3 of the present disclosure.

FIG. 16 is a schematic cross-sectional view of an example of a configuration of a photodetector according to a modification example 4 of the present disclosure.

FIG. 17 is a schematic cross-sectional view of an example of a configuration of a photodetector according to a second embodiment of the present disclosure.

FIG. 18 is a schematic view of an example of a planar layout of the photodetector illustrated in FIG. 17.

FIG. 19 is a block diagram illustrating a configuration example of an electronic apparatus including the photodetector illustrated in FIG. 1.

FIG. 20A is a schematic view of an example of an entire configuration of a photodetection system using the photodetector illustrated in FIG. 1 or the like.

FIG. 20B is a diagram illustrating an example of a circuit configuration of the photodetection system illustrated in FIG. 20A.

FIG. 21 is a view depicting an example of a schematic configuration of an endoscopic surgery system.

FIG. 22 is a block diagram depicting an example of a functional configuration of a camera head and a camera control unit (CCU).

FIG. 23 is a block diagram depicting an example of a schematic configuration of a vehicle control system.

FIG. 24 is a diagram of assistance in explaining an example of installation positions of an outside-vehicle information detecting section and an imaging section.

### DESCRIPTION OF EMBODIMENTS

Some embodiments of the present disclosure are described below in detail with reference to the drawings. The following description is a specific example of the present disclosure, and the present disclosure is not limited to the following embodiments. In addition, the present disclosure is not limited to arrangements, di-mensions, dimension ratios, etc. of respective components illustrated in each drawing. It is to be noted that the description is given in the following order.
1. First Embodiment (An example using an on-chip lens as an opening adjustment structure)
2. Modification Examples
2-1. Modification Example 1 (An example Using an Inner Lens as the Opening Adjustment Structure)
2-2. Modification Example 2 (Another Example Using the Inner Lens as the Opening Adjustment Structure)
2-3. Modification Example 3 (An Example Using an On-Chip Lens and an Inner Lens as the Opening Adjustment Structure)
2-4. Modification Example 4 (A Layout Example of an On-Chip Lens in a Layout in Which Pixels of the Same Color are Adjacent to Each Other)
3. Second Embodiment (An example Using a Color Filter Layer as the Opening Adjustment Structure)
4. Application Examples
5. Practical Application Examples

### 1. First Embodiment

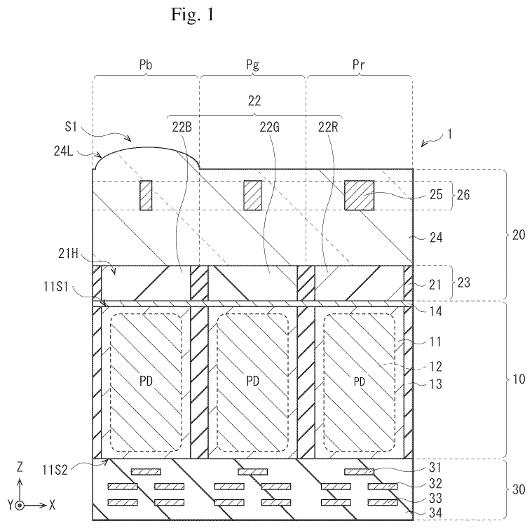

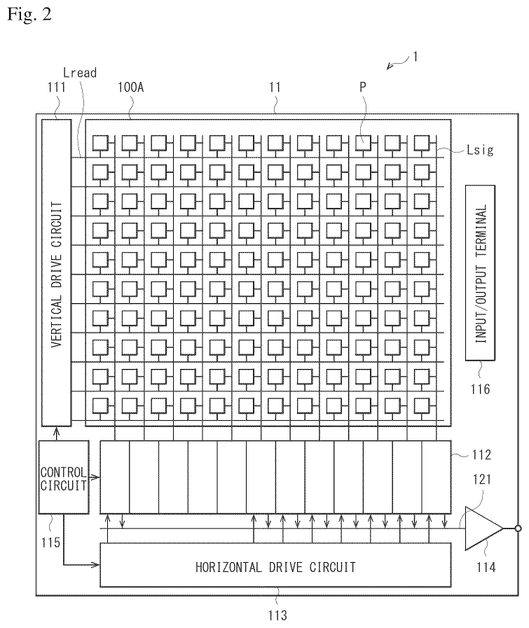

FIG. 1 schematically illustrates an example of a cross-sectional configuration of a photodetector (photodetector 1) according to a first embodiment of the present disclosure. FIG. 2 illustrates an example of an entire configuration of the photodetector 1 illustrated in FIG. 1. The photodetector 1 is, for example, a Complementary Metal Oxide Semiconductor (CMOS) image sensor or the like used in an electronic apparatus such as a digital still camera or a video camera, and includes, as an imaging region, a pixel section (pixel section 100A) including a plurality of pixels two-dimensionally arranged in a matrix. The photodetector 1 is, for example, a so-called back-illuminated photodetector in the CMOS image sensor or the like.

### Schematic Configuration of Photodetector

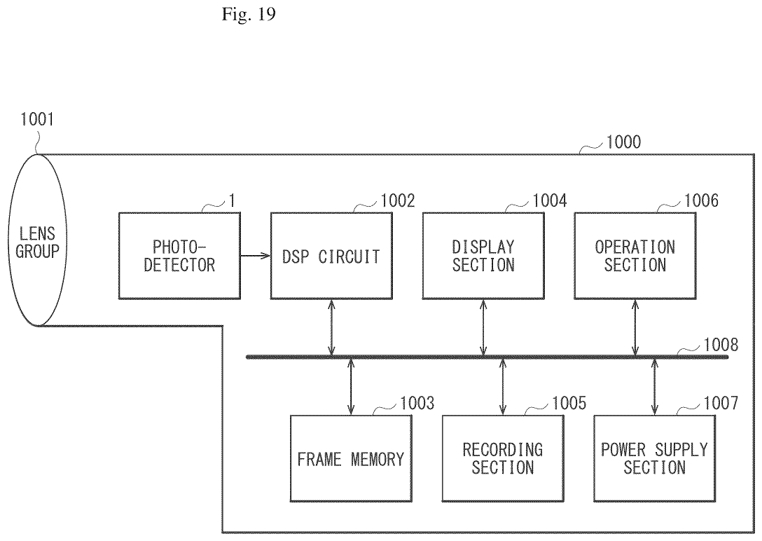

The photodetector 1 captures incident light (image light) from a subject through an optical lens system (e.g., a lens group 1001, see FIG. 19), converts the amount of light from the incident light of which an image is formed on an imaging plane into an electric signal on a pixel-by-pixel basis, and outputs the electrical signal as a pixel signal. The photodetector 1 includes the pixel section 100A as the imaging region on a semiconductor substrate 11, and includes, for example, a vertical drive circuit 111, a column signal processing circuit 112, a horizontal drive circuit 113, an output circuit 114, a control circuit 115, and an input/output terminal 116 in a peripheral region of the pixel section 100A.

The pixel section 100A includes, for example, a plurality of unit pixels P two-dimensionally arranged in a matrix. The plurality of unit pixels P each photoelectrically converts, in a photodiode PD, a subject image formed by an imaging lens to generate a signal for image generation.

For example, the unit pixels are wired to a pixel drive line Lread (specifically, a row selection line and a reset control line for each pixel row) and are wired to a vertical signal line Lsig for each pixel column. The pixel drive line Lread transmits a drive signal for signal reading from a pixel. The pixel drive line Lread has one end coupled to an output end corresponding to each row of the vertical drive circuit 111.

The vertical drive circuit 111 includes a shift register, an address decoder, and the like, and is a pixel driving section that drives the respective unit pixels P in the pixel section 100A in row units, for example. A signal output from each of the unit pixels P in a pixel row selected and scanned by the vertical drive circuit 111 is supplied to the column signal processing circuit 112 through a corresponding one of the vertical signal lines Lsig. The column signal processing circuit 112 includes an amplifier, a horizontal selection switch, and the like, provided for each of the vertical signal lines Lsig.

The horizontal drive circuit 113 includes a shift register, an address decoder, and the like, and drives respective horizontal selection switches of the column signal processing circuits 112 in sequence while scanning the horizontal selection switches. Such selective scanning by the horizontal drive circuit 113 causes the signals of respective pixels transmitted through respective vertical signal lines Lsig, to be output in sequence to a horizontal signal line 121 and to be transmitted outside of the semiconductor substrate 11 through the horizontal signal line 121.

The output circuit 114 performs signal processing on the signals supplied in sequence from the respective column signal processing circuits 112 through the horizontal signal line 121, and outputs the processed signals. The output circuit 114 may perform, for example, only buffering, or may perform black level adjustment, column variation correction, various types of digital signal processing, and the like.

Circuit components including the vertical drive circuit 111, the column signal processing circuit 112, the horizontal drive circuit 113, the horizontal signal line 121, and the output circuit 114 may be formed directly on the semiconductor substrate 11 or may be provided in an external control integrated circuit (IC). Alternatively, these circuit components may be formed on another substrate coupled by a cable or the like.

The control circuit 115 receives a clock signal provided from outside of the semiconductor substrate 11, or data, or the like, gives an instruction as to an operation mode, and also outputs data such as internal information about the photodetector 1.

The control circuit 115 further includes a timing generator that generates various timing signals, and controls driving of peripheral circuits such as the vertical drive circuit 111, the column signal processing circuit 112, and the horizontal drive circuit 113, based on the various timing signals generated by the timing generator.

The input/output terminal 116 exchanges signals with the outside.

### Circuit Configuration of Unit Pixel

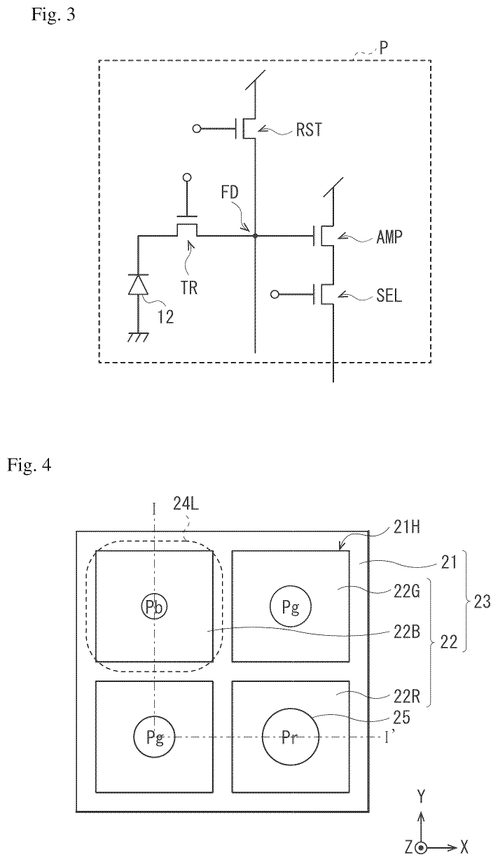

FIG. 3 illustrates an example of a readout circuit of the unit pixel P of the photodetector 1 illustrated in FIG. 2. The unit pixel P includes, for example, one photoelectric converter 12, a transfer transistor TR, a floating diffusion FD, a reset transistor RST, an amplification transistor AMP, and a selection transistor SEL, as illustrated in FIG. 3.

The photoelectric converter 12 includes a photodiode (PD). The photoelectric converter 12 includes an anode coupled to a ground voltage line and a cathode coupled to a source of the transfer transistor TR.

The transfer transistor TR is coupled between the photoelectric converter 12 and the floating diffusion FD. A drive signal TRsig is applied to a gate electrode of the transfer transistor TR. In a case where the drive signal TRsig is turned to an active state, a transfer gate of the transfer transistor TR is turned to an electrically conductive state, and a signal electric charge accumulated in the photoelectric converter 12 is transferred to the floating diffusion FD through the transfer transistor TR.

The floating diffusion FD is coupled between the transfer transistor TR and the amplification transistor AMP. The floating diffusion FD converts the electrical charge signal transferred by the transfer transistor TR into a voltage signal through electrical charge-voltage conversion, and outputs the voltage signal to the amplification transistor AMP.

The reset transistor RST is coupled between the floating diffusion FD and a power supply section. A drive signal RSTsig is applied to a gate electrode of the reset transistor RST. In a case where the drive signal RSTsig is turned to the active state, a reset gate of the reset transistor RST is turned to the electrically conductive state, and a potential of the floating diffusion FD is reset to a level of the power supply section.

The amplification transistor AMP has a gate electrode coupled to the floating diffusion FD, and a drain electrode coupled to the power supply section and serves as an input section of a readout circuit for a voltage signal held by the floating diffusion FD, that is, a so-called source follower circuit. In other words, the amplification transistor AMP has a source electrode coupled to the vertical signal line Lsig through the selection transistor SEL, thereby configuring a source follower circuit with a constant current source coupled to one end of the vertical signal line Lsig.

The selection transistor SEL is coupled between the source electrode of the amplification transistor AMP and the vertical signal line Lsig. A drive signal SELsig is applied to a gate electrode of the selection transistor SEL. In a case where the drive signal SELsig is turned to the active state, the selection transistor SEL is turned to the electrically conductive state to turn the unit pixel P to a selection state. Accordingly, a readout signal (pixel signal) output from the amplification transistor AMP is outputted to the vertical signal line Lsig through the selection transistor SEL.

### Configuration of Unit Pixel

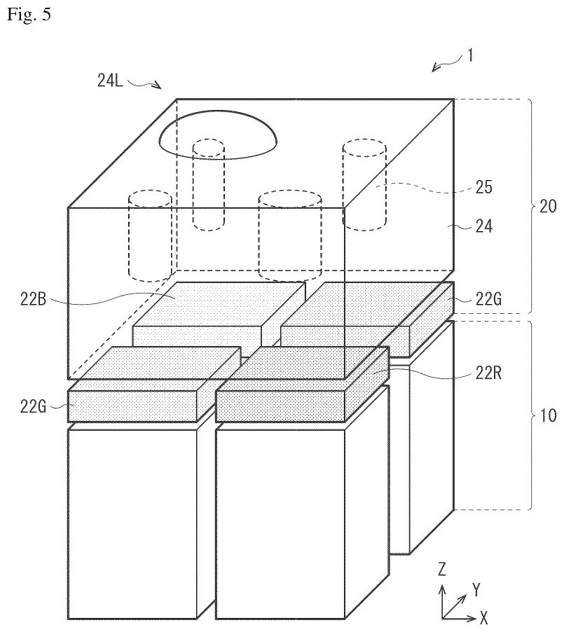

FIG. 4 schematically illustrates an example of a planar layout of the photodetector 1 illustrated in FIG. 1. FIG. 1 illustrates a cross-sectional configuration of the photodetector 1 corresponding to a line I-I′ illustrated in FIG. 4. FIG. 5 is a schematic perspective view of the photodetector 1 having the perspective layout illustrated in FIG. 4. The photodetector 1 is, for example, a back-illuminated photodetector as described above, and the plurality of unit pixels P two-dimensionally arranged in a matrix in the pixel section 100A each has, for example, a configuration in which a light-receiving section 10, a light-guiding section 20, and a multilayer wiring layer 30 are stacked. The light-guiding section 20 is provided on the light incident side S1 of the light-receiving section 10. The multilayer wiring layer 30 is provided on the side opposite to the light incident side S1 of the light-receiving section 10.

The light-receiving section 10 includes the semiconductor substrate 11 and a plurality of photoelectric converters 12. The semiconductor substrate 11 has a first surface 11S1 and a second surface 11S2 opposed to each other. The plurality of photoelectric converters 12 is formed so as to be embedded in the semiconductor substrate 11. The semiconductor substrate 11 includes, for example, a silicon substrate. Each of the photoelectric converters 12 is, for example, a Positive Intrinsic Negative (PIN) type photodiode (PD) and includes a pn junction in a predetermined region of the semiconductor substrate 11. As described above, one of the photoelectric converters 12 is formed so as to be embedded in each of the unit pixels P.

The light receiving section 10 further includes an element isolator 13.

The element isolator 13 is provided between adjacent unit pixels P. In other words, the element isolator 13 is provided around the unit pixels P, and is provided, for example, in a lattice form in the pixel section 100A. The element isolator 13 is provided to electrically and optically isolate adjacent unit pixels P from each other.

The element isolator 13 extends, for example, from the first surface 11S1 of the semiconductor substrate 11 towards the second surface 11S2 of the semiconductor substrate. It is possible to form the element isolator 13, for example, by diffusing a p-type impurity. In addition, the element isolator 13 may have a Shallow Trench Isolation (STI) structure or a Full Trench Isolation (FFTI) structure in which an opening is formed in the semiconductor substrate 11 from the first surface 11S1. A side surface and a bottom surface of the opening are covered with a fixed electrical charge layer 14 and an insulating layer is embedded in the opening. In addition, an air gap may be formed in the STI structure and in the FFTI structure.

The fixed electric charge layer 14 is further provided on the first surface 11S1 of the semiconductor substrate 11. The fixed electric charge layer 14 also serves to prevent reflection of light at the first surface 11S1 of the semiconductor substrate 11. The fixed electric charge layer 14 may be a film having a positive fixed electric charge or may be a film having a negative fixed electric charge. The constituent material of the fixed electric charge layer 14 includes a semiconductor material or an electrically conductive material having a band gap wider than the band gap of the semiconductor substrate 11. Specific examples of the semiconductor material and the electrically conductive material include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOx), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), aluminum oxynitride (AlOₓN_{y}), and the like. The fixed electric charge layer 14 may be a single-layer film, or may be a stacked layered film including different materials.

The light-guiding section (e.g., light guide) 20 includes, for example, a color filter layer 23 and a transparent layer 24 on the light incident side S1 of the light-receiving section 10 and guides light incident from the light incident side S1 to side of the light-receiving section 10. The color filter layer 23 includes, for example, a partition wall 21 and a color filter 22. The transparent layer 24 includes a wavelength separation layer 26 that includes a light-dispersing section 25 provided for each unit pixel P, and an on-chip lens 24L is provided on a surface on the light incident side S1 of the transparent layer 24.

The partition wall 21 is provided at a boundary between adjacent unit pixels P, and is a frame body having an opening 21H for each unit pixel P. In other words, the partition wall 21 is provided around the unit pixels P similarly to the element isolator 13 and is provided in a lattice form in the pixel section 100A. The partition wall 21 prevents obliquely incident light from the light incident side S1 from being leaked into adjacent unit pixels P. It is possible to form the partition wall 21 with, for example, a material having a refractive index lower than the refractive index of the color filter 22.

The partition wall 21 may also serve as a light shield for the unit pixel P that determines an optical black level. In addition, the partition wall 21 may also serve as a light shield for suppressing the occurrence of noise to peripheral circuits provided in the peripheral region of the pixel section 100A. In this case, it is possible to form the partition wall 21 with, for example, materials having a light-shielding property.

Examples of such material include tungsten (W), silver (Ag), copper (Cu), titanium (Ti), aluminum (Al), and alloys thereof. The examples of such materials further include a metal compound such as TiN. The partition wall 21 may be formed, for example, as a single-layer film or a stacked layered film. In a case where the partition wall 21 is formed as a stacked layered film, for example, a layer including Ti, tantalum (Ta), W, cobalt (Co), molybdenum (Mo), or an alloy thereof, a nitride thereof, an oxide thereof, or a carbide thereof may be provided as a base layer.

The color filter 22 allows light having a predetermined wavelength to selectively pass therethrough, and includes, for example, a red filter 22R, a green filter 22G, and a blue filter 22B. The red filter 22R allows red light (R) to selectively pass therethrough. The green filter 22G allows green light (G) to selectively pass therethrough. The blue filter 22B allows blue light (B) to selectively pass therethrough. Each opening 21H of the partition wall 21 is filled with a corresponding one of the color filters 22R, 22G, and 22B. Specifically, regarding the respective color filters 22R, 22G, and 22B, for example, as illustrated in FIG. 4, in four-unit pixels P arranged in two rows by two columns, two green filters 22G are provided on a first diagonal line, and one red filter 22R and one blue filter 22B are provided on a second diagonal line orthogonal to the first diagonal line. In each of the unit pixels P provided with a corresponding one of the color filters 22R, 22G, and 22B, for example, light of a corresponding color is selectively photoelectrically converted in a corresponding one of the photoelectric converters 12.

In other words, in the pixel section 100A, the unit pixels P (red pixels Pr) that selectively receive and photoelectrically convert red light (R), the unit pixels P (green pixels Pg) that selectively receive and photoelectrically convert green light (G), and the unit pixels P (blue pixels Pb) that selectively receive and photoelectrically convert blue light (B) are arranged in a Bayer pattern. The red pixel Pr, the green pixel Pg, and the blue pixel Pb respectively generate a pixel signal of a red light (R) component, a pixel signal of a green light (G) component, and a pixel signal of a blue light (B) component. This makes it possible for the photodetector 1 to obtain pixel signals of RGB.

The color filter 22 may include filters that each allow a corresponding one of cyan, magenta, and yellow to selectively pass therethrough. In each of the unit pixels P provided with a corresponding one of the color filters 22R, 22G, and 22B, for example, light of a corresponding color is detected in a corresponding one of the photoelectric converters 12. It is possible to form the color filter 22, for example, by dispersing a pigment or a dye into a resin material. The film thickness of the color filter 22 may differ for each color in consideration of color reproducibility and sensor sensitivity by a spectral spectrum thereof.

The transparent layer 24 allows light to pass therethrough. The transparent layer 24 has, for example, a refractive index of 1.5 or less for light (incident light) incident from the light incident side S1. The transparent layer 24 is formed with, for example, silicon oxide (SiO₂), fluorine-doped silicon oxide (SiOF), a fluorine resin, porous silica, or a mixed material thereof.

The wavelength separation layer 26 including the light-dispersing section 25, is provided in a layer of the transparent layer 24 as described above. The wavelength separation layer 26 corresponds to a specific example of a “wavelength separation structure” of the present disclosure. The wavelength separation structure includes a first material and a second material that have refractive indices different from each other. In the present embodiment, the light-dispersing section 25 provided for each unit pixel P corresponds to the “second material”, and the transparent layer 24 around the light-dispersing section 25 corresponds to the “first material”.

The wavelength separation layer 26 separates the incident light on each unit pixel P into a predetermined wavelength component and a wavelength component other than the predetermined wavelength component by one or a plurality of the light-dispersing sections 25 that is planarly and discretely provided for each unit pixel P. The wavelength separation layer 26 also selectively guides the predetermined wavelength component to the unit pixel P provided with the light-dispersing section 25 and guides the wavelength component other than the predetermined wavelength component to another unit pixel P. The wavelength separation layer 26 causes a phase delay of the incident light by a difference between the refractive index of the light-dispersing section 25 and the refractive index of the first material (the transparent layer 24) around the light-dispersing section 25 and affects a wavefront. The wavelength separation layer 26 is also referred to as a region (spectral region) where the incident light is dispersed by the light-dispersing section 25.

The light-dispersing section 25 includes one or a plurality of minute structure bodies provided for each unit pixel P, and has, for example, a columnar structure (pillar structure) having a size equal to or less than a predetermined wavelength of the incident light. The light-dispersing section 25 has a size, a shape, a refractive index, and the like that are determined so as to allow light in each wavelength range included in the incident light to be branched and propagate in a desired direction. Parameters related to a phase difference of the light-dispersing section 25 include the refractive index of the medium and the height and diameter of the light-dispersing section 25. For example, the light-dispersing sections 25 provided for the respective color pixels Pr, Pg, and Pb each have, for example, a diameter of 50 nm or more and 500 nm or less. It is sufficient if the height of the light-dispersing section 25 corresponds to about one frequency of the wavelength of the incident light, and the height of the light-dispersing section 25 is, for example, 500 nm or more and 1500 nm or less.

In each of the light-dispersing sections 25 provided for the respective color pixels Pr, Pg, and Pb, a phase delay amount differs depending on the wavelength of light, thereby changing the propagation direction of light for each wavelength range. For example, light having a wavelength of red light (R) entering the red pixel Pr is guided as it is to the photoelectric converter 12 of the red pixel Pr, and light having a wavelength other than the wavelength of the red light (R) propagates to the photoelectric converters 12 of the green pixel Pg and the blue pixel Pb adjacent to the red pixel Pr. For example, light having a wavelength of green light (G) entering the green pixel Pg, is guided as it is to the photoelectric converter 12 of the green pixel Pg, and light having a wavelength other than the wavelength of the green light (G) propagates to the photoelectric converters 12 of the red pixel Pr and the blue pixel Pb adjacent to the green pixel Pg. For example, light having a wavelength of blue light (B) entering the blue pixel Pb is guided as it is to the photoelectric converter 12 of the blue pixel Pb, and light having a wavelength other than the wavelength of the blue light (B) propagates to the photoelectric converters 12 of the red pixel Pr and the green pixel Pg adjacent to the blue pixel Pb.

The light-dispersing section 25 has a refractive index higher than the refractive index of the transparent layer 24 around the light-dispersing section 25, and has, for example, a refractive index of 1.7 or more for light (incident light) incident from the light incident side S1. The light-dispersing section 25 is formed of a material having a refractive index higher than the refractive index of the transparent layer 24. The light-dispersing section 25 is formed of, for example, titanium oxide (TiO₂), aluminum oxide (Al₂O₃), silicon nitride (Si₃N₄), amorphous silicon (a-Si), or a mixed material thereof.

It is to be noted that the light-dispersing sections 25 provided for the respective pixels Pr, Pg, and Pb may be formed of the same material or may be formed of different materials.

The on-chip lens 24L as a light-condensing element is selectively provided for, for example, the blue pixel Pb on the surface on the light incident side S1 of the transparent layer 24. This on-chip lens 24L corresponds to a specific example of an “opening adjustment structure” of the present disclosure. The opening adjustment structure causes an effective pixel opening size of a color pixel (e.g., the blue pixel Pb) having a relatively low light sensitivity to be larger than effective pixel opening sizes of the other color pixels (e.g., the red pixel Pr and the green pixel Pg). Selectively providing the on-chip lens 24L for the blue pixel Pb makes it possible to improve sensitivity of light having a wavelength of blue light (B) in the blue pixel Pb, and to adjust the sensitivity balance of the respective color pixels Pr, Pg, and Pb.

The on-chip lens 24L may be formed of the same materials as the materials of the transparent layer 24 or may be formed of materials different from the materials of the transparent layer 24. Examples of the materials of the on-chip lens 24L include inorganic materials such as silicon nitride (Si₃N4), silicon oxynitride (SiON), and amorphous silicon (a-Si), in addition to the materials described as the material of the transparent layer 24. In addition, the on-chip lens 24L may be formed of an organic material having a high refractive index such as an episulfide-based resin, a thietane compound, or resin thereof. There is no particular limitation as to the shape of the on-chip lens 24L, and it is possible to employ various types of lens shapes such as a half-sphere shape or a half-tubular shape.

The multilayer wiring layer 30 is provided on the side opposite to the light incident side S1 of the light-receiving section 10. Specifically, the multilayer wiring layer 30 is provided on the side of the second surface 11S2 of the semiconductor substrate 11. The multilayer wiring layer 30 has a configuration in which a plurality of wiring layers 31, 32, and 33 is stacked with an interlayer insulating layer 34 interposed therebetween. In addition to the readout circuit described above, the vertical drive circuit 111, the column signal processing circuit 112, the horizontal drive circuit 113, the output circuit 114, the control circuit 115, the input/output terminal 116, and the like, are formed on the multilayer wiring layer 30, for example.

The wiring layers 31, 32, and 33 are formed of, for example, aluminum (Al), copper (Cu), tungsten (W), or the like. In addition, the wiring layers 31, 32, and 33 may be formed using polysilicon (poly-Si).

For example, the interlayer insulating layer 34 includes a single-layer film including one type from among silicon oxide (SiOₓ), TEOS, silicon nitride (SiNₓ), silicon oxynitride (SiOₓN_{y}), and the like, or includes a stacked layered film including two or more types from among these materials.

### Workings and Effects

In the photodetector 1 according to the present embodiment, the on-chip lens 24L is selectively provided for a color pixel (e.g., the blue pixel Pb) having relatively low light sensitivity on the surface on the light incident side S1 of the transparent layer 24 including the wavelength separation layer 26 that includes, for example, one or a plurality of light-dispersing sections 25 planarly and discretely provided for each unit pixel P. This improves the sensitivity of blue light (B) in the blue pixel Pb. This is described below.

In recent years, as measures against a decrease in the sensitivity of pixels caused by advancement in microfabrication, attention has been focused on a technology for in-creasing an effective light-condensing region for each color to larger than a single pixel by scattering light by a nanopost structure to spatially perform wavelength separation. The nanopost structure has a high refractive index for a surrounding material, and a phase difference corresponding to a wavelength is caused between the nanopost structure and the material. Accordingly, optimizing the radius, length, and position of a nanopost makes it possible to distribute visible wavelength bands corresponding to respective color pixels included in a pixel unit. This makes it possible to achieve high sensitivity, as compared with a full-color image sensor that obtains RGB color information by a typical color filter.

However, the nanopost structure is a microstructure having a sub-wavelength scale (e.g., a diameter of several tens of nm to several hundreds of nm) with respect to a light wavelength. Accordingly, in order to improve the sensitivity ratio of three colors of RGB in a balanced way while maximizing sensitivity, precise size control and position control of the nanopost structure are necessary, which causes an adverse effect such as an increase in manufacturing difficulty and an increase in cost.

For example, in an image sensor having improved light efficiency by the nanopost structure described above, a layout is adopted in which a nanopost having a relatively large diameter is disposed in the middle of the unit pixel and a thin nanopost having a different diameter is disposed at a pixel boundary. These nanopost structures separate incident light into spatially different positions for each color using wavelength de-pendence of a phase difference caused by the nanoposts; however, a distance between the spatially different positions is small. Accordingly, the smaller the pixel size of a CMOS image sensor, the easier it is to adopt the nanopost structure. Specifically, with a minute pixel having a pixel size of 1.0 mm or less, an advantageous effect is achieved.

As one example, in a case where one nanopost is disposed in the middle of a pixel of 0.8 mm ′ 0.8 mm, an interval between adjacent nanoposts in each of a row direction and a column direction is 0.8 mm. Furthermore, in a case where a nanopost is disposed between the adjacent nanoposts, an interval between the nanoposts is 0.4 mm that is extremely narrow. However, the nanoposts are isolated; therefore, it is necessary to dispose nanoposts at intervals of at least about 100 nm or with a diameter of at least about 100 nm. Furthermore, in order to provide a phase difference of 2 pi for a desired wavelength with use of a relative difference in refractive index between a surrounding material and the nanopost, a certain level of the height of the nanopost is necessary.

The certain level of height is about 500 nm to about 1500 nm. Accordingly, in the case of a thin nanopost, an aspect ratio between the diameter and the height is increased to about 1:10, which causes a significant technical issue in manufacturing.

In contrast, in the present embodiment, the wavelength separation layer 26 includes the light-dispersing sections 25, for example, one for each unit pixel P as a wavelength separation structure in a layer of the transparent layer 24 provided on side of the first surface 11S1 (the light incident side S1) of the semiconductor substrate 11. An on-chip lens 24L is selectively provided for a color pixel (e.g., the blue pixel Pb) having a relatively low light sensitivity on the surface of the light incident side S1 of the transparent layer 24, which increases an effective pixel opening size of the blue pixel Pb.

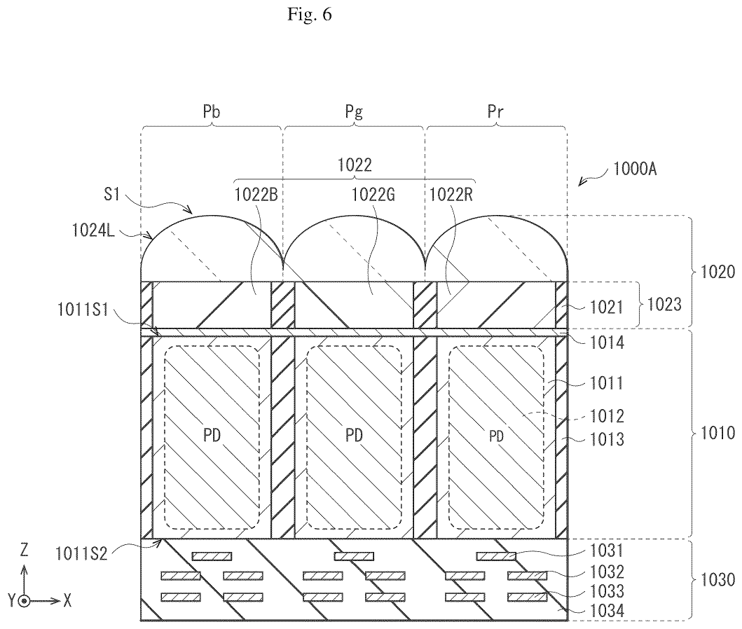

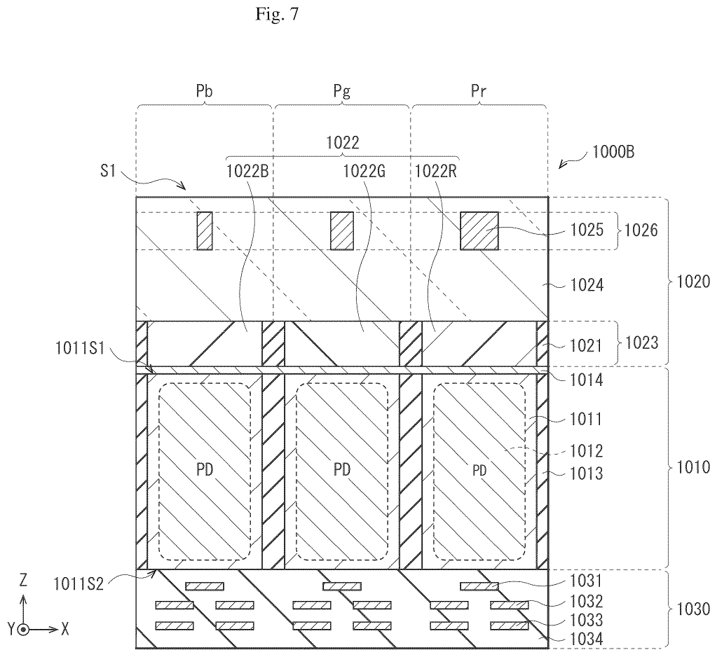

FIG. 6 schematically illustrates a cross-sectional configuration of a photodetector 1000A as a reference example 1. FIG. 7 schematically illustrates a cross-sectional configuration of a photodetector 1000B as a reference example 2. As with the photodetector 1, the photodetector 1000A includes a light-receiving section 1010, a light-guiding section 1020, and a multilayer wiring layer 1030 that are stacked. The light-guiding section 1020 is provided on the light incident side S1 of the light-receiving section 1010. The multilayer wiring layer 1030 is provided on the side opposite to the light incident side S1 of the light-receiving section 1010. The light-receiving section 1010 includes a semiconductor substrate 1011, a plurality of photoelectric converters 1012, and an element isolator 1013. The semiconductor substrate 1011 has a first surface 1011S1 and a second surface 1011S2 opposed to each other. The plurality of photoelectric converters 1012 is embedded in the semiconductor substrate 1011. The element isolator 1013 is provided between adjacent photoelectric converters 1012. The light-guiding section 1020 includes a color filter layer 1023. The color filter layer 1023 includes a partition wall 1021 and a color filter 1022. The color filter 1022 includes color filters 1022R, 1022G, and 1022B. An on-chip lens 1024L is provided for each of the color pixels Pr, Pg, and Pb on the color filter layer 1023. In the multilayer wiring layer 1030, a plurality of wiring layers 1031, 1032, and 1033 are stacked with an interlayer insulating layer 1034 interposed therebetween. In the photodetector 1000B, a transparent layer 1024 is provided on the color filter layer 1023 of the photodetector 1000A, and a wavelength separation structure 1026 that includes light-dispersing sections 1025 provided one for each of the color pixels Pr, Pg, and Pb is provided in a layer of the transparent layer 1024 similarly to the photodetector 1.

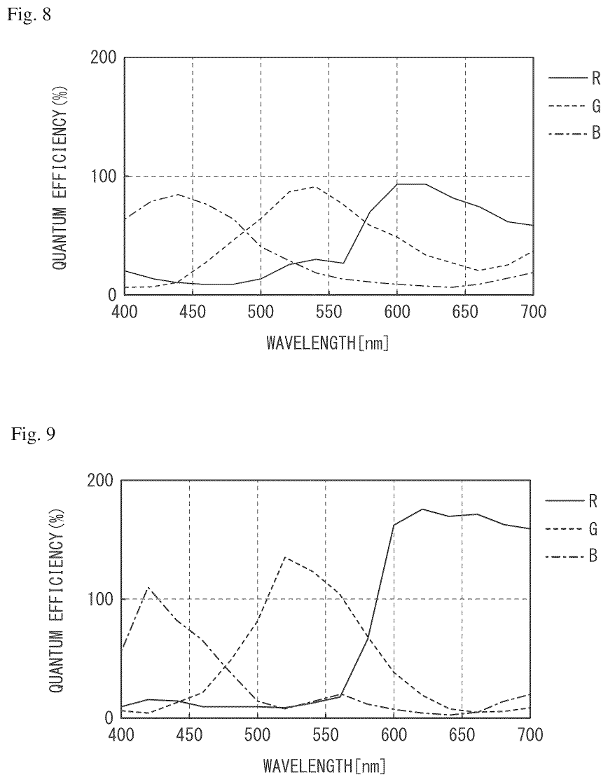

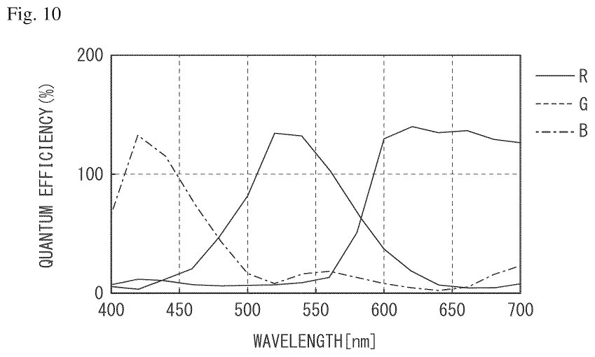

FIG. 8 illustrates quantum efficiencies of red light (R), green light (G), and blue light (B) in the photodetector 1000A. FIG. 9 illustrates quantum efficiencies of red light (R), green light (G), and blue light (B) in the photodetector 1000B. FIG. 10 illustrates quantum efficiencies of red light (R), green light (G), and blue light (B) in the photodetector 1. As can be seen from FIGS. 8 and 9, while the sensitivity of RGB is improved by providing the wavelength separation structure 1026 including the light-dispersing sections 1025 that are provided one for each of the color pixels Pr, Pg, and Pb, the balance of RGB is lost. In contrast, in the photodetector 1 (FIG. 10) in which the on-chip lens 24L is selectively provided for the blue pixel Pb having a relatively low light sensitivity on the surface on the light incident side S1 of the transparent layer 24 in the photodetector 1000B, quantum efficiency of blue light (B) is improved, and quantum efficiency of red light (R) is decreased, thereby improving the balance of RGB.

Accordingly, while the sensitivity of RGB is improved by a simple wavelength separation structure, variations in the sensitivity is corrected by a simple method of selectively providing the on-chip lens 24L as an opening adjustment structure for a color pixel (e.g., the blue pixel Pb) having a relatively low light sensitivity.

Thus, in the photodetector 1 according to the present embodiment, it is possible to improve sensitivity and improve color balance.

In addition, in the photodetector 1 according to the present embodiment, while sensitivity is improved by a simple wavelength separation structure that includes the light-dispersing sections 25 for each unit pixel P, variations in the sensitivity is corrected by a simple opening adjustment structure in which the on-chip lens 24L is selectively provided for a color pixel (e.g., the blue pixel Pb) having a relatively low light sensitivity. This makes it possible to reduce manufacturing difficulties and manufacturing costs, as compared with an image sensor in which only a nanopost structure is provided. Moreover, the sensitivity ratio balance of three colors of RGB is improved while maximizing sensitivity.

Next, a description is given of modification examples 1 to 4 of the present disclosure and a second embodiment of the present disclosure. Hereinafter, components similar to those in the first embodiment described above are denoted by the same reference numerals, and descriptions thereof are omitted as appropriate.

### 2. Modification Examples

### 2-1. Modification Example 1

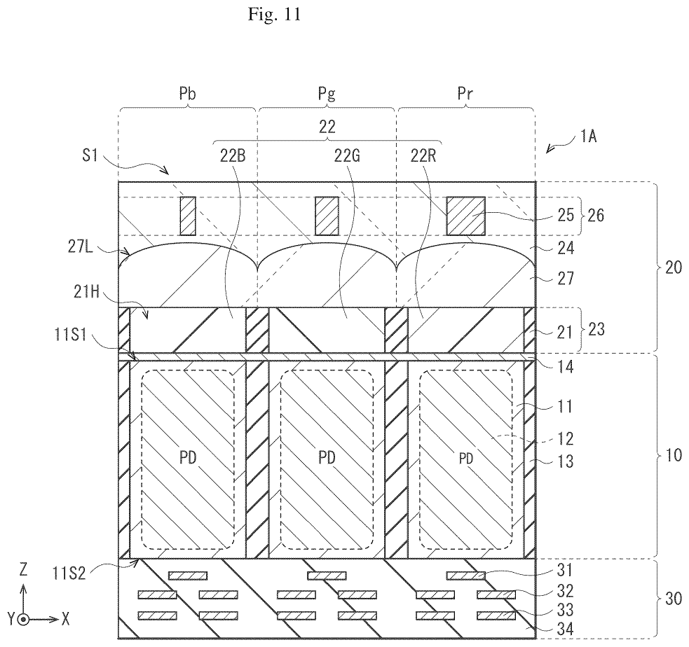

FIG. 11 schematically illustrates an example of a cross-sectional configuration of a photodetector (photodetector 1A) according to modification example 1 of the present disclosure. The photodetector 1A is, for example, a CMOS image sensor, or the like, used in an electronic apparatus such as a digital still camera or a video camera, and is, for example, a so-called back-illuminated photodetector, as with the first embodiment described above.

In the first embodiment described above, an example has been described in which color balance is improved by selectively providing the on-chip lens 24L for a color pixel (e.g., the blue pixel Pb) having a relatively low light sensitivity. In contrast, in the photodetector 1A according to the present modification example, in place of the on-chip lens 24L, an inner lens layer 27 is provided between the color filter layer 23 and the transparent layer 24. An inner lens 27L is provided for each of the color pixels Pr, Pg, and Pb on a surface of the inner lens layer 27. Except for these points, the photodetector 1A has a configuration substantially similar to that of the photodetector 1 according to the first embodiment described above.

The inner lens layer 27 corresponds to a specific example of an “opening adjustment structure” of the present disclosure. For example, the inner lens layer 27 is provided to cover an entire surface of the pixel section 100A, and, for example, a plurality of inner lenses 27L is provided without gaps on the surface of inner lens layer 27. Each of the inner lenses 27L guides incident light from above to the photoelectric converter 12 and is provided for each of the color pixels Pr, Pg, and Pb, as illustrated in FIG. 11.

It is possible to form the inner lens layer 27 including the inner lenses 27L of, for example, an inorganic material such as silicon oxide (SiO₂), silicon nitride (Si₃N₄), silicon oxynitride (SiON), or amorphous silicon (a-Si). In addition, the inner lens layer 27 may be formed of an organic material having a high refractive index such as an episulfide-based resin, a thietane compound, or resin thereof. There is no particular limitation as to the shape of the inner lens 27L, and it is possible to employ various types of lens shapes such as a half-sphere shape or a half-tubular shape.

Thus, in the photodetector 1A according to the present modification example, the inner lens layer 27 that includes one inner lens 27L provided for each of the color pixels Pr, Pg, and Pb is provided between the color filter layer 23 and the transparent layer 24. This makes it possible to achieve effects similar to those in the first embodiment described above.

### 2-2. Modification Example 2

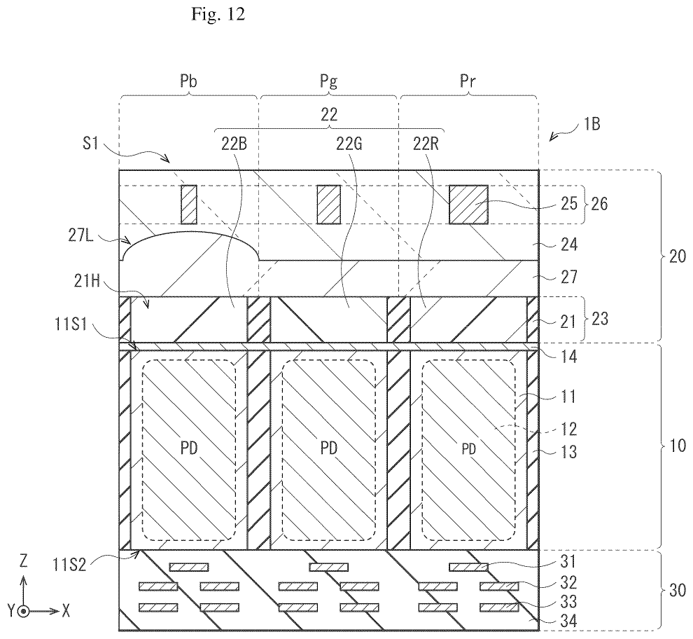

FIG. 12 schematically illustrates an example of a cross-sectional configuration of a photodetector (photodetector 1B) according to modification example 2 of the present disclosure. The photodetector 1B is, for example, a CMOS image sensor, or the like, used in an electronic apparatus such as a digital still camera or a video camera, and is, for example, a so-called back-illuminated photodetector, as with the first embodiment described above.

In modification example 1 described above, an example has been described in which the inner lens layer 27 is provided that includes one inner lens 27L provided for each of the color pixels Pr, Pg, and Pb. In contrast, in the photodetector 1B according to the present modification example, the inner lens 27L is selectively provided for a color pixel (e.g., the blue pixel Pb) having a relatively low light sensitivity on the surface of the inner lens layer 27. Except for this point, the photodetector 1B has a configuration substantially similar to that of the photodetector 1A according to modification example 1 described above.

Thus, in the photodetector 1B according to the present modification example, the inner lens 27L is selectively provided for a color pixel (e.g., the blue pixel Pb) having a relatively low light sensitivity on the surface of the inner lens layer 27. Even in such a configuration, it is possible to achieve effects similar to those in the first embodiment described above.

### 2-3. Modification Example 3

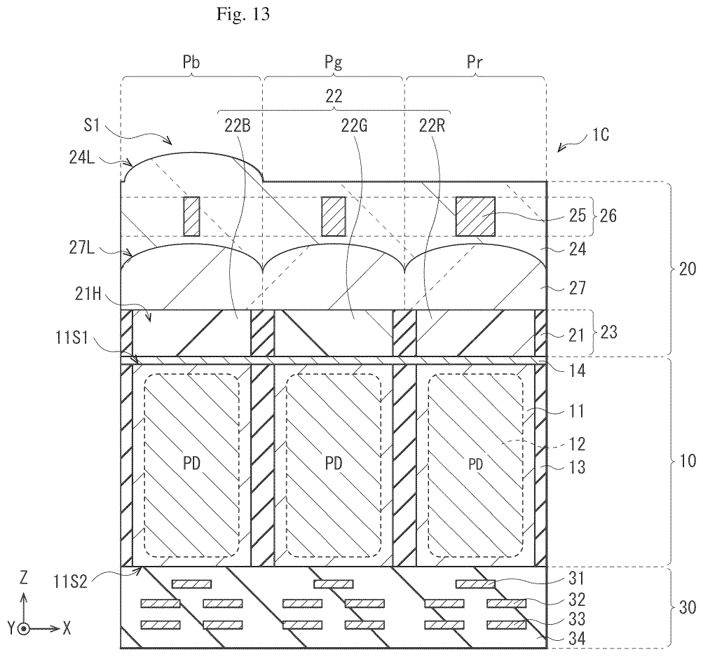

FIG. 13 schematically illustrates an example of a cross-sectional configuration of a photodetector (photodetector 1C) according to modification example 3 of the present disclosure. The photodetector 1C is, for example, a CMOS image sensor, or the like, used in an electronic apparatus such as a digital still camera or a video camera, and is, for example, a so-called back-illuminated photodetector, as with the first embodiment described above.

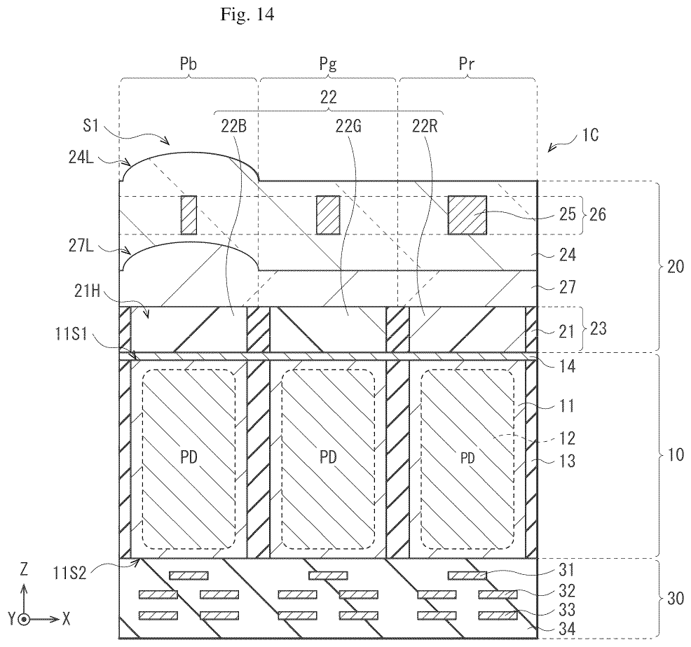

The first embodiment and modification examples 1 and 2 described above may be combined as appropriate. In other words, it is possible to use both the on-chip lens 24L and the inner lens 27L (the inner lens layer 27) as a “opening adjustment structure” of the present disclosure. For example, as illustrated in FIG. 13, the inner lens layer 27 that includes one inner lens 27L provided for each of the color pixels Pr, Pg, and Pb may be provided between the color filter layer 23 and the transparent layer 24, and the on-chip lens 24L may be further selectively provided for a color pixel (e.g., the blue pixel Pb) having a relatively low light sensitivity. For example, as illustrated in FIG. 14, the inner lens layer 27 that includes the inner lens 27L selectively provided for a color pixel (e.g., the blue pixel Pb) having a relatively low light sensitivity may be provided between the color filter layer 23 and the transparent layer 24, and the on-chip lens 24L may be further selectively provided for the color pixel (e.g., the blue pixel Pb) having a relatively low light sensitivity.

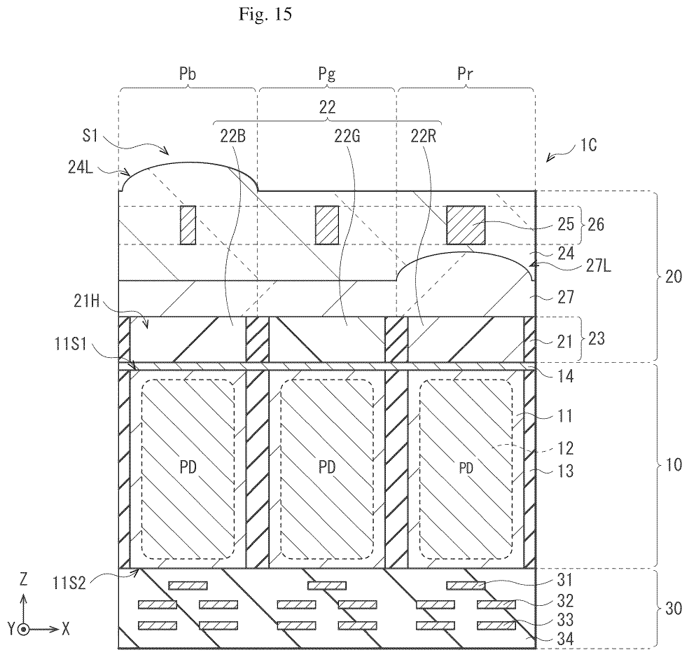

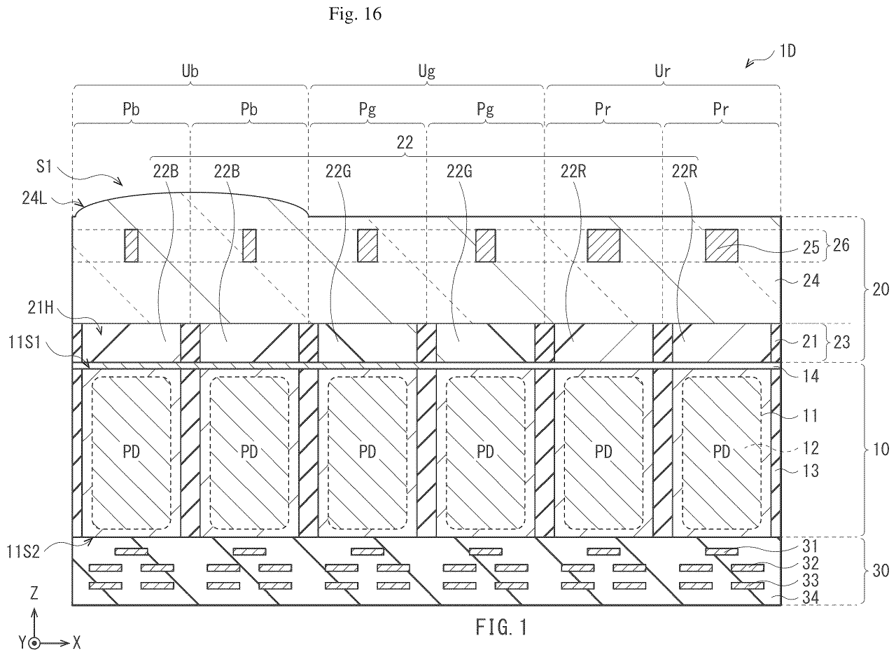

In addition, in a case where the on-chip lens 24L and the inner lens 27L are selectively provided for any of the color pixels Pr, Pg, and Pb, it is not necessary to provide both the on-chip lens 24L and the inner lens 27L for the same color pixel (e.g., the blue pixel Pb). For example, as illustrated in FIG. 15, the on-chip lens 24L may be selectively provided for the blue pixel Pb, and the inner lens 27L may be selectively provided for the red pixel Pr.

Even in such a configuration, it is possible to achieve effects similar to those in the first embodiment described above.

### 2-4. Modification Example 4

FIG. 16 schematically illustrates an example of a cross-sectional configuration of a photodetector (photodetector 1D) according to modification example 4 of the present disclosure. The photodetector 1D is, for example, a CMOS image sensor, or the like, used in an electronic apparatus such as a digital still camera or a video camera, and is, for example, a so-called back-illuminated photodetector, as with the first embodiment described above.

In the first embodiment described above, an example has been described in which the color pixels Pr, Pg, and Pb are arranged in a Bayer pattern. However, the arrangement of the color pixels Pr, Pg, and Pb in the pixel section 100A is not limited thereto. For example, a color pixel group in which a plurality of color pixels of the same color, (that is a plurality of color pixels Pr, Pg, or Pb arranged, for example, in two rows by two columns or three rows by three columns referred to as a color pixel unit (a red pixel unit Ur, a green pixel unit Ug, or a blue pixel unit Ub), may be arranged in a Bayer pattern. In this case, as illustrated in FIG. 16, one on-chip lens 24L is provided for a color pixel unit (e.g., the blue pixel unit Ub) having a relatively low light sensitivity in which the pixels of the same color are disposed adjacent to each other. In other words, in the photodetector 1D in which the color pixel units Ur, Ug, and Ub each including pixels of the same color disposed adjacent to each other and are disposed in a Bayer pattern, one on-chip lens 24L is disposed for the color pixel unit so as to be shared by the color pixels disposed adjacent to each other (e.g., the blue pixels Pb disposed adjacent to each other in two rows by two columns).

Even in such a configuration, it is possible to achieve effects similar to those in the first embodiment described above.

### 3. Second Embodiment

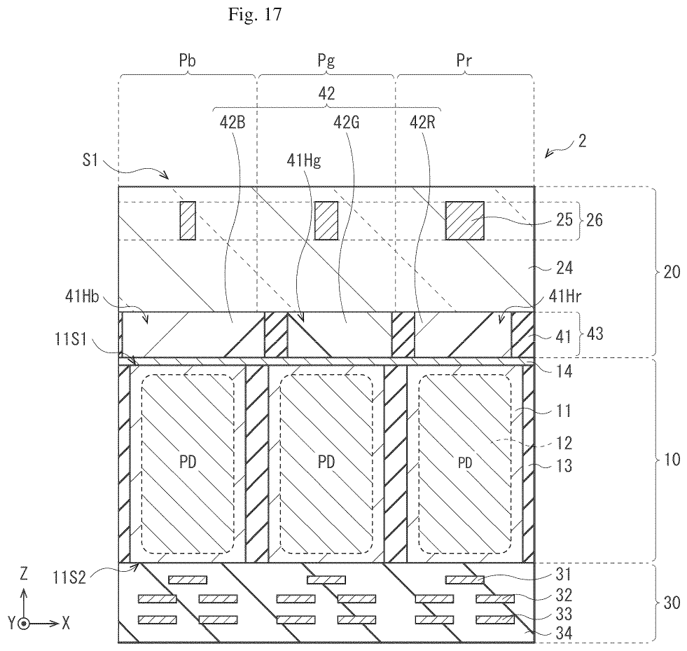

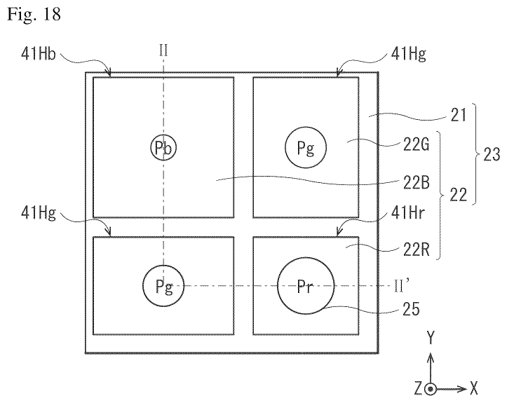

FIG. 17 schematically illustrates an example of a cross-sectional configuration of a photodetector (photodetector 2) according to a second embodiment of the present disclosure. FIG. 18 schematically illustrates an example of a planar layout of the photodetector 2 illustrated in FIG. 17. FIG. 17 illustrates a cross-sectional configuration of the photodetector 2 corresponding to a line II-II′ illustrated in FIG. 18.

The photodetector 2 according to the present embodiment does not include the on-chip lens 24L and uses a color filter layer 43 as a specific example of an “opening adjustment structure” of the present disclosure. Except for this point, the photodetector 2 has a configuration substantially similar to that of the photodetector 1 according to the first embodiment described above.

The color filter layer 43 includes, for example, a partition wall 41 and a color filter 42, similar to the first embodiment described above.

The partition wall 41 is provided at a boundary between adjacent unit pixels P, and is a frame body having an opening 41H for each unit pixel P. In other words, the partition wall 41 is provided around the unit pixels P similarly to the element isolator 13 and is provided in a lattice form in the pixel section 100A. The partition wall 41 prevents obliquely incident light from the light incident side S1 from being leaked into adjacent unit pixels P. It is possible to form the partition wall 41 of, for example, a material having a refractive index lower than the refractive index of the color filter 22.

The partition wall 41 may also serve as a light shield of the unit pixel P that determines an optical black level. In addition, the partition wall 41 may also serve as a light shield for suppressing the occurrence of noise to peripheral circuits provided in the peripheral region of the pixel section 100A. In this case, it is possible to form the partition wall 41 of, for example, materials having a light-shielding property. Examples of such materials include tungsten (W), silver (Ag), copper (Cu), titanium (Ti), aluminum (Al), and alloys thereof. The examples of such a material further include a metal compound such as TiN. The partition wall 41 may be formed, for example, as a single-layer film or a stacked layered film. In a case where the partition wall 41 is formed as a staked layered film, for example, a layer including Ti, tantalum (Ta), W, cobalt (Co), molybdenum (Mo), or an alloy thereof, a nitride, an oxide thereof, or carbide thereof may be provided as a base layer.

In the present embodiment, the openings 41H of the partition wall 41 have different sizes corresponding to the light sensitivities of the color pixels Pr, Pg, and Pb. For example, as illustrated in FIGS. 17 and 18, an opening 41Hb of the blue pixel Pb having a relatively low light sensitivity is larger than openings 41Hr and 41Hg of the red pixel Pr and the green pixel Pg, and the opening 41Hr of the red pixel Pr has a relatively high light sensitivity is smaller than the openings 41Hg and 41Hb of the green pixel Pg and the blue pixel Pb. In other words, the sizes of the openings 41Hr, 41Hg, and 41Hb of the color pixels Pr, Pg, and Pb are 41Hr<41Hg<41Hb.

The color filter 42 allows light having a predetermined wavelength to selectively pass therethrough, and includes, for example, a red filter 42R, a green filter 42G, and a blue filter 42B. The red filter 42R allows light having a wavelength of red light (R) to selectively pass therethrough. The green filter 42G allows light having a wavelength of green light (G) to selectively pass therethrough. The blue filter 42B allows light having a wavelength of blue light (B) to selectively pass therethrough. Each opening 41H of the partition wall 41 is filled with a corresponding one of the color filters 42R, 42G, and 42B. Specifically, regarding the respective color filters 42R, 42G, and 42B, for example, as illustrated in FIG. 18, in four-unit pixels P arranged in two rows by two columns, two green filters 42G are provided on a first diagonal line, and one red filter 42R and one blue filter 42B are provided on a second diagonal line orthogonal to the first diagonal line. Each of the unit pixels P is provided with a corresponding one of the color filters 42R, 42G, and 42B, for example, and light of a corresponding color is selectively photoelectrically converted in a corresponding one of the photoelectric converters 12.

In other words, in the pixel section 100A, the unit pixels P (red pixels Pr) that selectively receive and photoelectrically convert red light (R), the unit pixels P (green pixels Pg) that selectively receive and photoelectrically convert green light (G), and the unit pixels P (blue pixels Pb) that selectively receive and photoelectrically convert blue light (B) are arranged in a Bayer pattern. The red pixel Pr, the green pixel Pg, and the blue pixel Pb respectively generate a pixel signal of a red light (R) component, a pixel signal of a green light (G) component, and a pixel signal of a blue light (B) component. This makes it possible for the photodetector 2 to obtain pixel signals of RGB.

The color filter 42 may include filters that each allow a corresponding one of cyan, magenta, and yellow to selectively pass therethrough. In the unit pixels P, each provided with a corresponding one of the color filters 42R, 42G, and 42B, for example, light of a corresponding color is detected in a corresponding one of the photoelectric converters 12. It is possible to form the color filter 42, for example, by dispersing a pigment or a dye into a resin material. The film thickness of the color filter 42 may differ for each color in consideration of color reproducibility and sensor sensitivity by a spectral spectrum thereof.

Accordingly, in the present embodiment, the wavelength separation layer 26 that includes the light-dispersing sections 25 for each unit pixel P, is provided as a wavelength separation structure in a layer of the transparent layer 24 provided on the first surface 11S1 (the light incident side S1) of the semiconductor substrate 11, and the sizes of the openings 41H of the partition wall 41 formed for the respective unit pixels P in the color filter layer 43 are larger for a color pixel (e.g., the blue pixel Pb) having relatively low light sensitivity of the color pixels Pr, Pg, and PB, and are smaller for a color pixel (e.g., the red pixel Pr) having relatively high light sensitivity. Accordingly, while sensitivity of RGB is improved by a simple wavelength separation structure, variation in sensitivity is corrected by a simple method.

Thus, in the photodetector 2 according to the present embodiment, it is possible to improve sensitivity and improve color balance.

In addition, in the photodetector 2 according to the present embodiment, while sensitivity is improved by a simple wavelength separation structure that includes the light-dispersing sections 25 for each unit pixel P, variation in sensitivity is corrected by a simple opening adjustment structure in which the sizes of the openings 41H of the partition wall 41 formed for respective unit pixels P in the color filter layer 43 are larger for a color pixel having relatively low light sensitivity of the color pixels Pr, Pg, and Pb, and are smaller for a color pixel having relatively high light sensitivity, which makes it possible to reduce manufacturing difficulty and manufacturing cost, as compared with an image sensor in which, only by a nanopost structure, sensitivity ratio balance of three colors of RGB is improved while maximizing sensitivity.

### 4. Application Examples

### Application Example 1

It is possible to apply the photodetector 1 or the like described above, for example, to a camera system such as a digital still camera or a video camera, a mobile phone or the like having an imaging function, and various types of electronic apparatuses having an imaging function. FIG. 19 illustrates a schematic configuration of an electronic apparatus 1000.

The electronic apparatus 1000 includes, for example, a lens group 1001, the photodetector 1, a digital signal processor (DSP) circuit 1002, a frame memory 1003, a display section 1004, a recording section 1005, an operation section 1006, and a power supply section 1007, which are coupled to each other through a bus line 1008.

The lens group 1001 captures incident light (image light) from a subject to form an image on an imaging plane of the photodetector 1. The photodetector 1 converts the amount of incident light of which the image is formed on the imaging plane through the lens group 1001 into an electrical signal on a pixel-by-pixel basis and supplies the electrical signal as a pixel signal to the DSP circuit 1002.

The DSP circuit 1002 is a signal processing circuit that processes a signal supplied from the photodetector 1. The DSP circuit 1002 outputs image data obtained by processing the signal from the photodetector 1. The frame memory 1003 temporality holds the image data processed by the DSP circuit 1002.

The display section 1004 includes, for example, a panel-type display device such as a liquid crystal panel or an organic Electro Luminescence (EL) panel and records image data of a moving image or a still image captured by the photodetector 1, on a recording medium such as a semiconductor memory or a hard disk.

In accordance with an operation by a user, the operation section 1006 outputs an operation signal regarding various functions of the electronic apparatus 1000. The power supply section 1007 supplies the DSP circuit 1002, the frame memory 1003, the display section 1004, the recording section 1005, and the operation section 1006 with various types of power as power for operating these supply targets as appropriate.

### Application Example 2

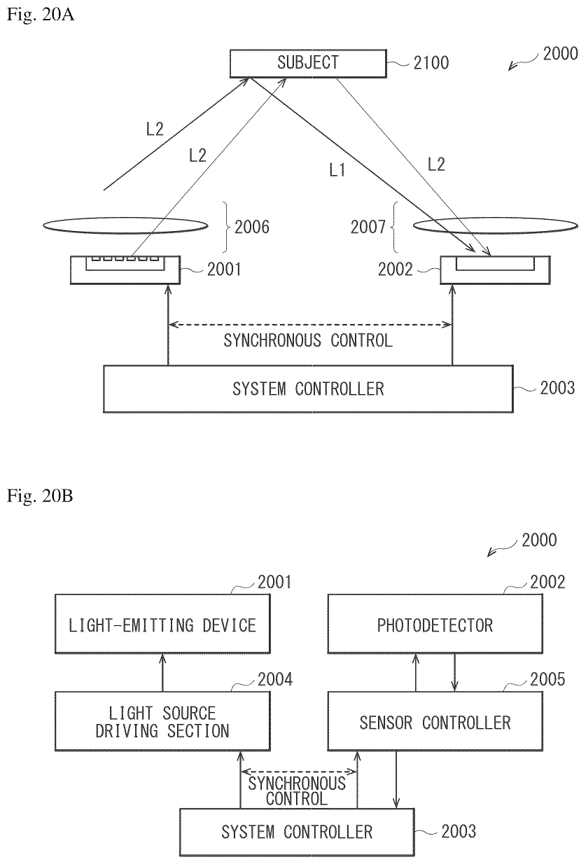

FIG. 20A schematically illustrates an example of an entire configuration of a photodetection system 2000 including the photodetector 1. FIG. 20B illustrates an example of a circuit configuration of the photodetection system 2000. The photodetection system 2000 includes a light-emitting device 2001 as a light source section that emits infrared light L2, and a photodetector 2002 as a light-receiving section including a photoelectric conversion element. As the photodetector 2002, it is possible to use the photodetector 1 described above. The photodetection system 2000 may further include a system controller 2003, a light source driving section 2004, a sensor controller 2005, a light source-side optical system 2006, and a camera-side optical system 2007.

The photodetector 2002 is able to detect light L1 and the light L2. The light L1 is ambient light from outside reflected by a subject (a measurement object) 2100 (FIG. 20A). The light L2 is light emitted from the light-emitting device 2001 and then reflected by the subject 2100. The light L1 is, for example, visible light, and the light L2 is, for example, infrared light. The light L1 is detectable by an photoelectric converter in the photodetector 2002, and the light L2 is detectable by a photoelectric conversion region in the photodetector 2002. It is possible to obtain image information of the subject 2100 from the light L1 and obtain distance information between the subject 2100 and the photodetection system 2000 from the light L2. It is possible to mount the photodetection system 2000 on, for example, an electronic apparatus such as a smartphone and a mobile body such as a car. It is possible to configure the light-emitting device 2001 with, for example, a semiconductor laser, a surface-emitting semiconductor laser, or a vertical cavity surface emitting laser (VCSEL). As a method of detecting the light L2 emitted from the light-emitting device 2001 by the photodetector 2002, for example, it is possible to adopt an iTOF method; however, the method is not limited thereto. In the iTOF method, the photoelectric converter is able to measure a distance to the subject 2100 by time of flight (Time-of-Flight; TOF), for example. As a method of detecting the light L2 emitted from the light-emitting device 2001 by the photodetector 2002, it is possible to adopt, for example, a structured light method or a stereovision method. For example, in the structured light method, light having a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to obtain two or more images of the subject 2100 viewed from two or more different viewpoints, thereby making it possible to measure the distance between the photodetection system 2000 and the subject 2100. It is to be noted that it is possible to synchronously control the light-emitting device 2001 and the photodetector 2002 by the system controller 2003.

### 5. Practical Application Examples

### Practical Application Example to Endoscopic Surgery System

The technology according to the present disclosure (present technology) is applicable to various products. For example, the technology according to the present disclosure may be applied to an endoscopic surgery system.

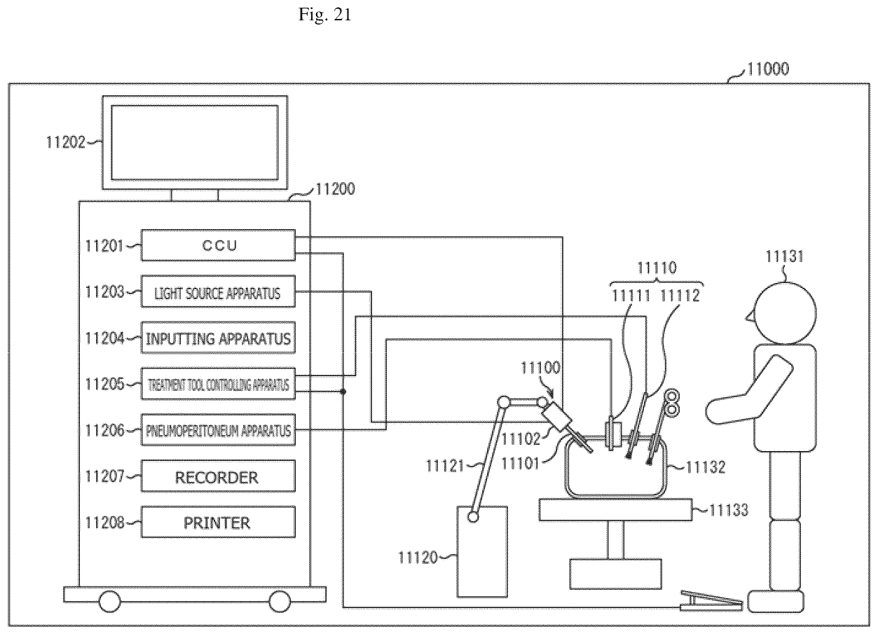

FIG. 21 is a view depicting an example of a schematic configuration of an endoscopic surgery system to which the technology according to an embodiment of the present disclosure (present technology) can be applied.

In FIG. 21, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 includes as a rigid endoscope having the lens barrel 11101 of the hard type. However, the endoscope 11100 may otherwise be included as a flexible endoscope having the lens barrel 11101 of the flexible type.

The lens barrel 11101 has at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pick-up element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as raw data to a camera control unit (CCU) 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (e.g., demosaic processing).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user may input an instruction, or the like, to change an image pick-up condition (type of irradiation light, magnification, focal distance or the like) by the endoscope 11100.

A treatment tool controlling apparatus 11205 controls driving of the energy device 11112 for cautery or incision of a tissue, sealing of a blood vessel, or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image, or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustments to the white balance of a picked-up image can be performed by the light source apparatus 11203. Further, in this case, if laser beams from the respective RGB laser light sources are irradiated time-divisionally on an observation target and driving of the image pick-up elements of the camera head 11102 are controlled in a synchronous manner with the irradiation timings. Then images individually corresponding to the R, G and B colors can be also picked up time-divisionally. According to this method, a color image can be obtained even if color filters are not provided for the image pick-up element.

Further, the light source apparatus 11203 may be controlled such that the intensity of light to be output is changed for each predetermined time. By controlling the driving of the image pick-up element of the camera head 11102 in synchronism with the timing of the change of the intensity of light to acquire images time-divisionally and synthesizing the images, an image of a high dynamic range, free from underexposed blocked up shadows and overexposed highlights, can be created.

Further, the light source apparatus 11203 may be configured to supply light of a pre-determined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observations, it is possible to perform observations of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

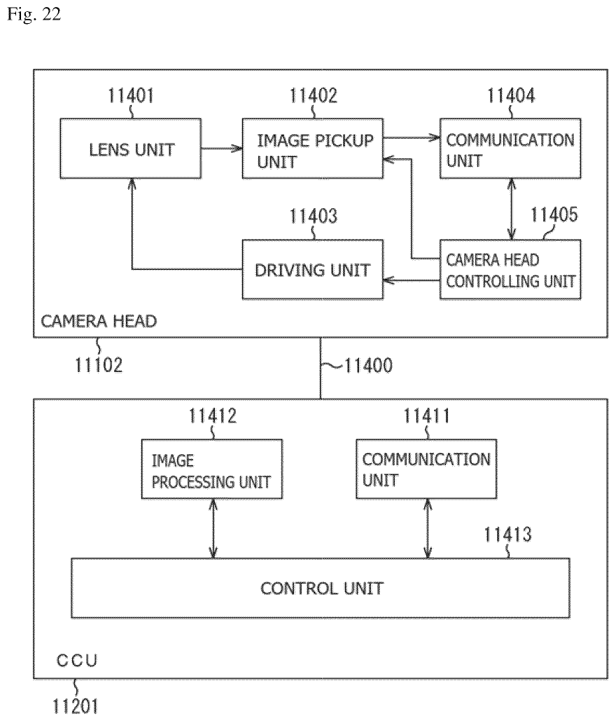

FIG. 22 is a block diagram depicting an example of a functional configuration of the camera head 11102 and the CCU 11201 depicted in FIG. 21.

The camera head 11102 includes a lens unit 11401, an image pick-up unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pick-up elements which is included by the image pick-up unit 11402 may be one (single-plate type) or a plural number (multi-plate type). Where the image pick-up unit 11402 is configured as that of the multi-plate type, for example, image signals corresponding to respective R, G and B are generated by the image pickup elements, and the image signals may be synthesized to obtain a color image.

The image pick-up unit 11402 may also be configured so as to have a pair of image pick-up elements for acquiring respective image signals for the right eye and the left eye ready for three-dimensional (3D) display. If 3D display is performed, then the depth of a living body tissue in a surgical region can be comprehended more accurately by the surgeon 11131. It is to be noted that, where the image pick-up unit 11402 is configured as a stereoscopic type, a plurality of systems of lens units 11401 are provided corresponding to the individual image pick-up elements.

Further, the image pick-up unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked-up image by the image pick-up unit 11402 can be suitably adjusted.

The communication unit 11404 includes a communication apparatus for transmitting and receiving various kinds of information to and from the CCU 11201. The communication unit 11404 transmits an image signal acquired from the image pick-up unit 11402 as raw data to the CCU 11201 through the transmission cable 11400.

In addition, the communication unit 11404 receives a control signal for driving the camera head 11102 from the CCU 11201 and supplies the control signal to the camera head controlling unit 11405. The control signal includes information relating to image pick-up conditions such as, for example, information that a frame rate of a picked-up image is designated, information that an exposure value upon image pick-up is designated and/or information that a magnification and a focal point of a picked-up image are designated.

It is to be noted that the image pick-up conditions such as the frame rate, exposure value, magnification or focal point may be designated by the user or may be set automatically by the control unit 11413 of the CCU 11201 based on an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 based on a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication, or the like.

The image processing unit 11412 performs various image processes for an image signal in the form of raw data transmitted thereto from the camera head 11102.

The control unit 11413 performs various kinds of control processes relating to image pick-up of a surgical region, or the like. by the endoscope 11100 and display of a picked-up, or the like. For example, the control unit 11413 creates a control signal for controlling driving of the camera head 11102.

Further, the control unit 11413 controls, based on an image signal for which image processes have been performed by the image processing unit 11412, the display apparatus 11202 to display a picked-up image in which the surgical region or the like is imaged. Thereupon, the control unit 11413 may recognize various objects in the picked-up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked-up image. The control unit 11413 may cause, when controlling the display apparatus 11202 to display a picked-up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both electrical and optical communications.

Here, while, in the example depicted, communication is performed by wired communication using the transmission cable 11400, the communication between the camera head 11102 and the CCU 11201, however, may be performed by wireless communication.

One example of the endoscopic surgery system to which the technology according to the present disclosure may be applied has been described above. The technology according to the present disclosure may be applied to, for example, the image pickup unit 11402 among the configurations described above. Applying the technology according to the present disclosure to the image pickup unit 11402 makes it possible to improve detection accuracy.

It is to be noted that the endoscopic surgery system has been described here as an example, but the technology according to the present disclosure may be additionally applied to, for example, a microscopic surgery system and the like.

(Practical Application Example to Mobile Body) The technology according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, a robot, a construction machine, an agricultural machine (tractor), or the like.

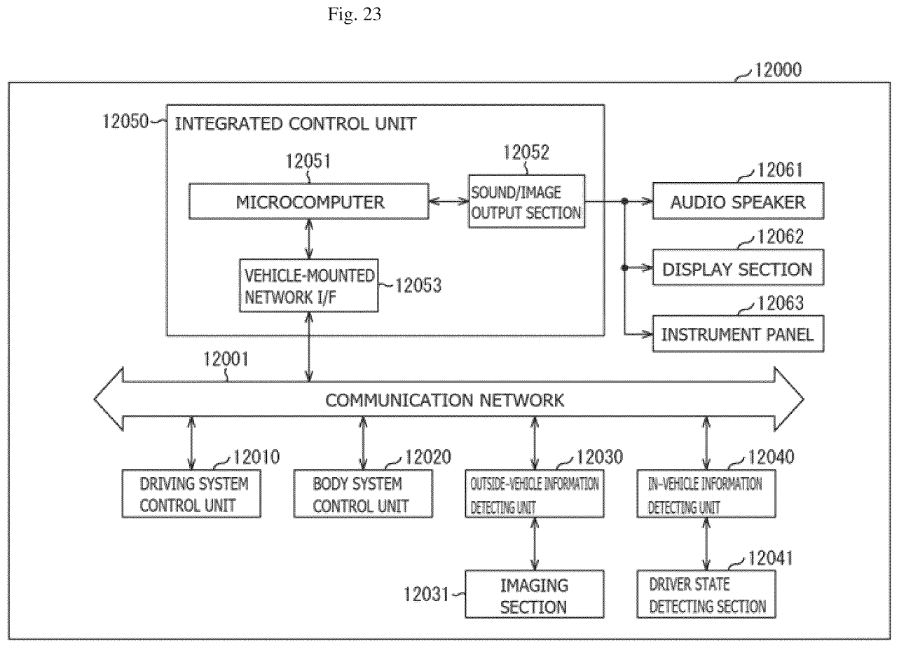

FIG. 23 is a block diagram depicting an example of a schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 23, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches, can be input to the body system control unit 12020. The body system control unit 12020 receives these input radio waves or signals, and controls a door lock device, the power window device, the lamps, or the like, of the vehicle.

The outside-vehicle information detecting unit 12030 detects information about the outside of the vehicle including the vehicle control system 12000. For example, the outside-vehicle information detecting unit 12030 is connected to an imaging section 12031. The outside-vehicle information detecting unit 12030 instructs the imaging section 12031 to provide an image of the outside of the vehicle and then receives the image from the imaging section 12031. Based on the received image, the outside-vehicle information detecting unit 12030 may process the received image to detect objects such as a human, a vehicle, an obstacle, a sign, a character on a road surface, or the like, or process the received image to detect distances from the objects.

The imaging section 12031 is an optical sensor that receives light, and outputs an electrical signal corresponding to a received amount of light. The imaging section 12031 can output the electrical signal as an image or can output the electrical signal as information about a measured distance. In addition, the light received by the imaging section 12031 may be visible light or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. Based on detection information input from the driver state detecting section 12041, the in-vehicle information detecting unit 12040 may calculate a degree of fatigue of the driver or a degree of concentration of the driver or may determine whether the driver is dozing off.

The microcomputer 12051 can calculate a control target value for the driving force generating device, the steering mechanism, or the braking device based on the information about the inside or outside of the vehicle obtained by the outside-vehicle information detecting unit 12030 or the in-vehicle information detecting unit 12040 and can output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, (e.g., operating the vehicle without input from driver, or the like), by controlling the driving force generating device, the steering mechanism, the braking device, or the like based on the information about the outside or inside of the vehicle obtained by the outside-vehicle information detecting unit 12030 or the in-vehicle information detecting unit 12040.

In addition, the microcomputer 12051 can output a control command to the body system control unit 12020 based on the information about the outside of the vehicle obtained by the outside-vehicle information detecting unit 12030. For example, the microcomputer 12051 can perform cooperative control intended to prevent a glare by controlling the headlamp to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display and a head-up display.

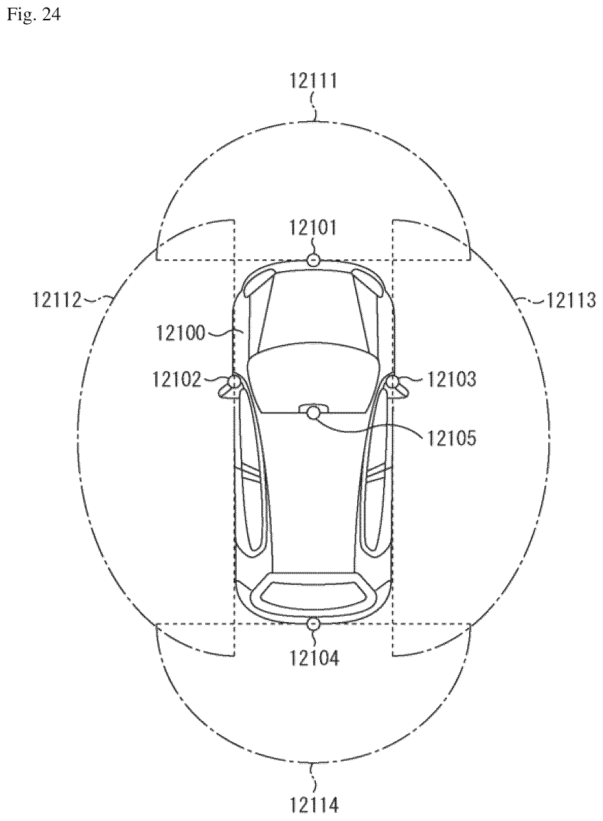

FIG. 24 is a diagram depicting an example of the installation position of the imaging section 12031.

In FIG. 24, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle, obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door, obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 24 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) based on the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance and perform automatic brake control (including following stop control), automatic acceleration control (including following start control), or the like. It is thus possible to perform cooperative control intended for automated driving that allows the vehicle to operate in an automated manner without depending on input from driver, or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects based on the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062 and performs forced deceleration or avoidance steering via the driving system control unit 12010.

The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether there is a pedestrian in images of the imaging sections 12101 to 12104. Such recognition of a pedestrian is, for example, performed by a procedure of extracting characteristic points in the images of the imaging sections 12101 to 12104 as infrared cameras and a procedure of determining whether it is the pedestrian by performing pattern matching processing on a series of characteristic points representing the contour of the object. When the microcomputer 12051 determines that there is a pedestrian in the images of the imaging sections 12101 to 12104, and thus recognizes the pedestrian, the sound/image output section 12052 controls the display section 12062 so that a square contour line for emphasis is displayed to be superimposed on the recognized pedestrian. The sound/image output section 12052 may also control the display section 12062 so that an icon or the like representing the pedestrian is displayed at a desired position.

One example of the vehicle control system to which the technology according to the present disclosure may be applied has been described above. The technology according to the present disclosure is appliable to the imaging section 12031 among the configurations described above. Specifically, the photodetector (e.g., the photodetector 1) according to any of the first and second embodiments described above and the modification examples 1 to 4 thereof is applicable to the imaging section 12031. Applying the technology according to the present disclosure to the imaging section 12031 makes it possible to obtain a high definition shot image with less noise. This makes it possible to perform highly accurate control with use of the shot image in the mobile body control system.

Although the present disclosure has been described above with reference to the first and second embodiments, the modification examples 1 to 4, the application examples, and the practical application examples, the present technology is not limited to the embodiments and the like described above and may be modified in a variety of ways. For example, the modification examples 1 to 4 described above have been described as modification examples of the first embodiment described above; however, configurations of the respective modification examples and the second embodiment may be combined as appropriate. For example, an “opening adjustment structure” of the present disclosure may have a configuration in which the color filter layer 23, and the on-chip lens 24L or the inner lens 27L are combined.

It is to be noted that the effects described herein are merely illustrative and non-limiting, and other effects may be provided.

It is to be noted that the present disclosure may have the following configurations.

According to the present technology having the following configurations, quantum efficiency in a pixel having relatively low light sensitivity is improved. This makes it possible to improve sensitivity and improve color balance.

(1)

A photodetector including:
a semiconductor substrate having a first surface and a second surface that are opposed to each other, and including a plurality of first pixels and a plurality of second pixels arranged in a matrix, the plurality of first pixels and the plurality of second pixels that selectively photoelectrically convert wavelengths different from each other;
a wavelength separation structure including media having refractive indices different from each other, the media planarly and discretely provided for each of the first pixels and the second pixels on side of the first surface, the wavelength separation structure that separates incident light on the first pixel into a first wavelength component and a wavelength component other than the first wavelength component and selectively guides the first wavelength component to the first pixel, and separates incident light on the second pixel into a second wavelength component and a wavelength component other than the second wavelength component and selectively guides the second wavelength component to the second pixel; and
an opening adjustment structure that is provided on side of the first surface and causes an effective pixel opening size of one pixel having relatively low light sensitivity of the first pixel and the second pixel to be larger than an effective pixel opening size of the other pixel.
   (2)

The photodetector according to (1), in which
the wavelength separation structure includes a first medium and a second medium, the first medium provided as a common layer for the first pixels and the second pixels, and
the second medium provided for each of the first pixels and the second pixels, and
the second medium has a columnar structure having a size equal to or less than a pre-determined wavelength of the incident light and has a refractive index higher than the first medium.
   (3)

The photodetector according to (2), in which one or a plurality of the second media is provided for each of the first pixels and the second pixels and has a diameter different for the first pixels and the second pixels.

(4)

The photodetector according to (2) or (3), in which the first medium has a refractive index of 1.5 or less for the incident light.

(5)

The photodetector according to any one of (2) to (4), in which t the first medium includes silicon oxide, fluorine-doped silicon oxide, a fluorine resin, porous silica, or a mixed material thereof.

(6)

The photodetector according to any one of (2) to (5), in which the second medium has a refractive index of 1.7 or more for the incident light.

(7)

The photodetector according to any one of (2) to (6), in which t the second medium includes titanium oxide, aluminum oxide, silicon nitride, amorphous silicon, or a mixed material thereof.

(8)

The photodetector according to any one of (1) to (7), in which the opening adjustment structure includes a light-condensing element selectively provided for the one pixel.

(9)

The photodetector according to (8), in which the light-condensing element includes an on-chip lens disposed closer to light incident side than the wavelength separation structure.

(10)

The photodetector according to (8) or (9), in which the light-condensing element includes an inner lens disposed between the first surface and the wavelength separation structure.

(11)

The photodetector according to any one of (8) to (10), in which in the semiconductor substrate, a plurality of the first pixels is adjacently disposed in a row direction and a column direction and a plurality of the second pixels is adjacently disposed in the row direction and the column direction, and
the light-condensing element is provided one for each of pixel groups having relatively low light sensitivity of first pixel groups each including the plurality of the first pixels adjacently disposed and second groups each including the plurality of the second pixels adjacently disposed.
   (12)

The photodetector according to any one of (1) to (11), in which the opening adjustment structure includes a frame body provided at a boundary between the first pixel and the second pixel adjacent to each other between the first surface and the wavelength separation structure, the frame body having an opening for each of the first pixel and the second pixel,
a size of the opening for the one pixel is larger than a size of the opening for the other pixel, and
each of the openings is filled with a color filter that allows a wavelength to selectively pass therethrough, the wavelength that is to be photoelectrically converted in each of the first pixel and the second pixel.
   (13)

The photodetector according to (12), in which the frame body includes a material having a refractive index lower than a refractive index of the color filter.

(14)

A photodetector including:
a semiconductor substrate having a first surface and a second surface that are opposed to each other, and including a plurality of first pixels and a plurality of second pixels arranged in a matrix, the plurality of first pixels and the plurality of second pixels that selectively photoelectrically convert wavelengths different from each other;
a wavelength separation structure including media having refractive indices different from each other, the media planarly and discretely provided for each of the first pixels and the second pixels on side of the first surface, the wavelength separation structure that separates incident light on the first pixel into a first wavelength component and a wavelength component other than the first wavelength component and selectively guides the first wavelength component to the first pixel, and separates incident light on the second pixel into a second wavelength component and a wavelength component other than the second wavelength component and selectively guides the second wavelength component to the second pixel; and
a light-condensing element provided, on side of the first surface, for a pixel having relatively low light sensitivity of the first pixel and the second pixel.
   (15)

The photodetector according to (14), in which the light-condensing element includes an on-chip lens disposed closer to light incident side than the wavelength separation structure.

(16)

The photodetector according to (14) or (15), in which the light-condensing element includes an inner lens disposed between the first surface and the wavelength separation structure.

(17)

A photodetector including:
a semiconductor substrate having a first surface and a second surface that are opposed to each other, and including a plurality of first pixels and a plurality of second pixels arranged in a matrix, the plurality of first pixels and the plurality of second pixels that selectively photoelectrically convert wavelengths different from each other;
a wavelength separation structure including media having refractive indices different from each other, the media planarly and discretely provided for each of the first pixels and the second pixels on side of the first surface, the wavelength separation structure that separates incident light on the first pixel into a first wavelength component and a wavelength component other than the first wavelength component and selectively guides the first wavelength component to the first pixel, and separates incident light on the second pixel into a second wavelength component and a wavelength component other than the second wavelength component and selectively guides the second wavelength component to the second pixel; and
a color filter layer provided between the first surface and the wavelength separation structure, and including a frame body and a color filter, the frame body provided at a boundary between the first pixel and the second pixel adjacent to each other and having an opening for each of the first pixel and the second pixel, each of the openings being filled with the color filter, the color filter that allows a wavelength to selectively pass therethrough, and the wavelength that is to be photoelectrically converted in each of the first pixel and the second pixel, in which
a size of the opening for a pixel having relatively low light sensitivity is larger than a size of the opening for another pixel.
   (18)

The photodetector according to (17), in which the frame body includes a material having a refractive index lower than a refractive index of the color filter.

(19)

A photodetector, comprising:
a plurality of first pixels and a plurality of second pixels arranged in a matrix in a semiconductor substrate having a first surface and a second surface that are opposed to each other,
wherein the plurality of first pixels and the plurality of second pixels photoelectrically convert light in different wavelengths from each other;
a wavelength separation structure including materials having refractive indices different from each other, the materials planarly and discretely provided for each first pixel of the plurality of first pixels and each second pixel of the plurality of second pixels on f the first surface of the semiconductor substrate,
wherein the wavelength separation structure separates incident light on a first pixel of the plurality of first pixels into a first wavelength component and a wavelength component other than the first wavelength component and selectively guides the first wavelength component to a photoelectric converter the first pixel, and separates the incident light on a second pixel into a second wavelength component and a wavelength component other than the second wavelength component and selectively guides the second wavelength component to a photoelectric converter of the second pixel; and
a sensitivity adjustment structure provided above the first surface of the semiconductor substrate, wherein the sensitivity adjustment structure improves a sensitivity of one of the first pixel or the second pixel.
   (20)

The photodetector according to (19), wherein
the materials include a first material and a second material, the first material provided as a common layer for the plurality of first pixels and the plurality of second pixels, and the second material provided for each first pixel of the first plurality of first pixels and for each second pixel of the plurality of second pixels, and
the second material has a columnar structure having a size equal to or less than a pre-determined wavelength of the incident light and has a refractive index higher than the first material.
   (21)

The photodetector according to (20), wherein the second material is provided for each first pixel of the plurality of first pixels and each second pixel of the plurality of the second pixels and has a diameter different for the plurality of the first pixels and the plurality of the second pixels.

(22)

The photodetector according to (20) or (21), wherein the first material has a refractive index of 1.5 or less for the incident light.

(23)

The photodetector according to (20) to (22), wherein the first material includes silicon oxide, fluorine-doped silicon oxide, a fluorine resin, porous silica, or a mixed material thereof.

(24)

The photodetector according to (20) to (23), wherein the second material has a refractive index of 1.7 or more for the incident light.

(25)

The photodetector according to (20) to (24), wherein the second material includes titanium oxide, aluminum oxide, silicon nitride, amorphous silicon, or a mixed material thereof.

(26)

The photodetector according to (20) to (25), wherein the sensitivity adjustment structure causes an effective pixel opening size of one of the first pixel or the second pixel which has a relatively low light sensitivity, to be larger than an effective pixel opening size of the other one of the first pixel or the second pixel.

(27)

The photodetector according to (19) to (26), wherein the sensitivity adjustment structure includes a light-condensing element selectively provided for the one of the first pixel or the second pixel.

(28)

The photodetector according to (27), wherein the light-condensing element comprises an on-chip lens disposed closer to the incident light than the wavelength separation structure.

(29)

The photodetector according to (27) or (28), wherein the light-condensing element comprises an inner lens disposed between the first surface of the semiconductor substrate and the wavelength separation structure.

(30)

The photodetector according to (28) to (29), wherein
in the semiconductor substrate, the plurality of the first pixels is disposed adjacent to each other in a row direction and a column direction and the plurality of the second pixels is disposed adjacent to each other in the row direction and the column direction, and
the light-condensing element is provided for of first pixel groups each including the plurality of the first pixels adjacently disposed and second pixel groups each including the plurality of the second pixels adjacently disposed each having a relatively low light sensitivity.
   (31)

The photodetector according to (19) to (30), wherein
the sensitivity adjustment structure includes a frame body provided at a boundary between the first pixel and the second pixel disposed adjacent to each other between the first surface of the semiconductor substrate and the wavelength separation structure, the frame body having an opening for each of the first pixel and the second pixel,
a size of the opening for the one of the first pixel or the second pixel is larger than a size of the opening for the other of the first pixel or the second pixel, and
each of the openings includes a color filter that allows light of a particular wavelength to pass through, the light is photoelectrically converted in each of the first pixel and the second pixel.
   (32)

The photodetector according to (31), wherein the frame body includes a third material having a refractive index lower than a refractive index of the color filter.

(33)

A photodetector, comprising:
a plurality of first pixels and a plurality of second pixels arranged in a matrix in a semiconductor substrate having a first surface and a second surface that are opposed to each other,
wherein the plurality of first pixels and the plurality of second pixels photoelectrically convert light in different wavelengths from each other;
a wavelength separation structure including materials having refractive indices different from each other, the materials planarly and discretely provided for each first pixel of the plurality of first pixels and each second pixel of the plurality of second pixels on the first surface of the semiconductor substrate,
wherein the wavelength separation structure separates incident light on a first pixel of the plurality of first pixels into a first wavelength component and a wavelength component other than the first wavelength component and selectively guides the first wavelength component to a photoelectric converter of the first pixel, and separates the incident light on a second pixel of the plurality of second pixels into a second wavelength component and a wavelength component other than the second wavelength component and selectively guides the second wavelength component to a photoelectric converter of the second pixel; and
a light-condensing element provided on the first surface of the semiconductor substrate for the first pixel or the second pixel having a relatively low light sensitivity.
   (34)

The photodetector according to (33), wherein the light-condensing element comprises an on-chip lens disposed closer to the incident light than the wavelength separation structure.

(35)

The photodetector according to (33) or (34), wherein the light-condensing element comprises an inner lens disposed between the first surface of the semiconductor substrate and the wavelength separation structure.

(36)

A photodetector, comprising:
a plurality of first pixels and a plurality of second pixels arranged in a matrix in a semiconductor substrate having a first surface and a second surface that are opposed to each other,
wherein the plurality of first pixels and the plurality of second pixels photoelectrically convert light in different wavelengths from each other;
a wavelength separation structure including materials having refractive indices different from each other, the materials planarly and discretely provided for each first pixel of the plurality of first pixels and each second pixel of the plurality of second pixels on the first surface of the semiconductor substrate,
wherein the wavelength separation structure separates incident light on a first pixel of the plurality of first pixels into a first wavelength component and a wavelength component other than the first wavelength component and selectively guides the first wavelength component to a photoelectric converter of the first pixel, and separates the incident light on a second pixel of the plurality of second pixels into a second wavelength component and a wavelength component other than the second wavelength component and selectively guides the second wavelength component to a photoelectric converter of the second pixel; and
a color filter layer provided between the first surface of the semiconductor substrate and the wavelength separation structure and including a frame body and a color filter, the frame body provided at a boundary between the first pixel and the second pixel adjacent to each other and having an opening for each of the first pixel and the second pixel, each of the openings including the color filter, the color filter allows light of a particular wavelength to passthrough, and the light is photoelectrically converted in each of the first pixel and the second pixel,
wherein a size of the opening for one of the first pixel or the second pixel having a relatively low light sensitivity is larger than a size of the opening for the other of the first pixel or the second pixel.
   (37) The photodetector according to (36), wherein the frame body includes a material having a refractive index lower than a refractive index of the color filter.
   (38)

The photodetector according to (36) or (37), wherein
the materials include a first material and a second material, the first material provided as a common layer for the plurality of first pixels and the plurality of second pixels, and the second material provided for each first pixel of the first plurality of first pixels and for each second pixel of the plurality of second pixels, and
the second material has a columnar structure having a size equal to or less than a pre-determined wavelength of the incident light and has a refractive index higher than the first material.

It should be understood by those skilled in the art that various modifications, combinations, sub-combinations, and alterations may occur depending on design requirements and other factors insofar as they are within the scope of the appended claims or the equivalents thereof.

### REFERENCE SIGNS LIST

1, 1A, 1B, 1C, 1D, 2 photodetector
10 light-receiving section
11 semiconductor substrate
12 photoelectric converter
13 element isolator
14 fixed electric charge layer
20 light-guiding section
21 partition wall
22 color filter
22B blue filter
22G green filter
22R red filter
23 color filter layer
24 transparent layer
24L on-chip lens
25 light-dispersing section
26 wavelength separation layer
27 inner lens layer
27L inner lens
30 multilayer wiring layer
31, 32, 33 wiring layer
34 interlayer insulating layer
11S1 first surface
11S2 second surface
S1 light incident side

What is claimed is:

1. A photodetector, comprising:
a plurality of first pixels and a plurality of second pixels arranged in a matrix in a semiconductor substrate having a first surface and a second surface opposed to each other,
wherein the plurality of first pixels and the plurality of second pixels photoelectrically convert light in different wavelengths from each other and wherein each first pixel of the plurality of first pixels and each second pixel of the plurality of second pixels each includes a color filter;
a wavelength separation structure including materials having refractive indices different from each other, the materials planarly and discretely provided for each first pixel of the plurality of first pixels and each second pixel of the plurality of second pixels on the first surface of the semiconductor substrate,
wherein the wavelength separation structure separates incident light on a first pixel of the plurality of first pixels into a first wavelength component and a wavelength component other than the first wavelength component and selectively guides the first wavelength component to a photoelectric converter the first pixel, and separates the incident light on a second pixel of the plurality of second pixels into a second wavelength component and a wavelength component other than the second wavelength component and selectively guides the second wavelength component to a photoelectric converter of the second pixel; and
a sensitivity adjustment structure provided above the first surface of the semiconductor substrate, wherein the sensitivity adjustment structure improves a sensitivity of one of the first pixel or the second pixel.

2. The photodetector according to claim 1, wherein
the materials include a first material and a second material, the first material provided as a common layer for the plurality of first pixels and the plurality of second pixels, and the second material provided for each first pixel of the first plurality of first pixels and for each second pixel of the plurality of second pixels, and
the second material has a columnar structure having a size equal to or less than a predetermined wavelength of the incident light and has a refractive index higher than the first material.

3. The photodetector according to claim 2, wherein the second material is provided for each first pixel of the plurality of first pixels and each second pixel of the plurality of the second pixels and has a diameter different for the plurality of the first pixels and the plurality of the second pixels.

4. The photodetector according to claim 2, wherein the first material has a refractive index of 1.5 or less for the incident light.

5. The photodetector according to claim 2, wherein the first material includes silicon oxide, fluorine-doped silicon oxide, a fluorine resin, porous silica, or a mixed material thereof.

6. The photodetector according to claim 2, wherein the second material has a refractive index of 1.7 or more for the incident light.

7. The photodetector according to claim 2, wherein the second material includes titanium oxide, aluminum oxide, silicon nitride, amorphous silicon, or a mixed material thereof.

8. The photodetector according to claim 1, wherein the sensitivity adjustment structure causes an effective pixel opening size of one of the first pixel or the second pixel which has a relatively low light sensitivity, to be larger than an effective pixel opening size of the other one of the first pixel or the second pixel.

9. The photodetector according to claim 8, wherein the sensitivity adjustment structure includes a light-condensing element selectively provided for the one of the first pixel or the second pixel.

10. The photodetector according to claim 9, wherein the light-condensing element comprises an on-chip lens disposed closer to the incident light than the wavelength separation structure.

11. The photodetector according to claim 9, wherein the light-condensing element comprises an inner lens disposed between the first surface of the semiconductor substrate and the wavelength separation structure.

12. The photodetector according to claim 9, wherein
in the semiconductor substrate, the plurality of the first pixels is disposed adjacent to each other in a row direction and a column direction and the plurality of the second pixels is disposed adjacent to each other in the row direction and the column direction, and
the light-condensing element is provided for of first pixel groups each including the plurality of the first pixels adjacently disposed and second pixel groups each including the plurality of the second pixels adjacently disposed each having a relatively low light sensitivity.

13. The photodetector according to claim 8, wherein
the sensitivity adjustment structure includes a frame body provided at a boundary between the first pixel and the second pixel disposed adjacent to each other between the first surface of the semiconductor substrate and the wavelength separation structure, the frame body having an opening for each of the first pixel and the second pixel,
a size of the opening for the one of the first pixel or the second pixel is larger than a size of the opening for the other of the first pixel or the second pixel, and
each of the openings exposes the color filters for the first pixel and the second pixel that allows light of a particular wavelength to pass through, the light is photoelectrically converted in each of the first pixel and the second pixel.

14. The photodetector according to claim 13, wherein
the frame body includes a third material having a refractive index lower than a refractive index of the color filter.

15. A photodetector, comprising:
a plurality of first pixels and a plurality of second pixels arranged in a matrix in a semiconductor substrate having a first surface and a second surface opposed to each other,
wherein the plurality of first pixels and the plurality of second pixels photoelectrically convert light in different wavelengths from each other;
a wavelength separation structure including materials having refractive indices different from each other, the materials planarly and discretely provided for each first pixel of the plurality of first pixels and each second pixel of the plurality of second pixels on the first surface of the semiconductor substrate,
wherein the wavelength separation structure separates incident light on a first pixel of the plurality of first pixels into a first wavelength component and a wavelength component other than the first wavelength component and selectively guides the first wavelength component to a photoelectric converter of the first pixel, and separates the incident light on a second pixel of the plurality of second pixels into a second wavelength component and a wavelength component other than the second wavelength component and selectively guides the second wavelength component to a photoelectric converter of the second pixel; and
a light-condensing element provided on the first surface of the semiconductor substrate for the first pixel or the second pixel having a relatively low light sensitivity.

16. The photodetector according to claim 15, wherein
the light-condensing element comprises an on-chip lens disposed closer to the incident light than the wavelength separation structure.

17. The photodetector according to claim 15, wherein
the light-condensing element comprises an inner lens disposed between the first surface of the semiconductor substrate and the wavelength separation structure.

18. A photodetector, comprising:
a plurality of first pixels and a plurality of second pixels arranged in a matrix in a semiconductor substrate having a first surface and a second surface opposed to each other,
wherein the plurality of first pixels and the plurality of second pixels photoelectrically convert light in different wavelengths from each other;
a wavelength separation structure including materials having refractive indices different from each other, the materials planarly and discretely provided for each first pixel of the plurality of first pixels and each second pixel of the plurality of second pixels on the first surface of the semiconductor substrate,
wherein the wavelength separation structure separates incident light on a first pixel of the plurality of first pixels into a first wavelength component and a wavelength component other than the first wavelength component and selectively guides the first wavelength component to a photoelectric converter of the first pixel, and separates the incident light on a second pixel of the plurality of second pixels into a second wavelength component and a wavelength component other than the second wavelength component and selectively guides the second wavelength component to a photoelectric converter of the second pixel; and
a color filter layer provided between the first surface of the semiconductor substrate and the wavelength separation structure and including a frame body and a color filter, the frame body provided at a boundary between the first pixel and the second pixel adjacent to each other and having an opening for each of the first pixel and the second pixel, each of the openings including the color filter, the color filter allows light of a particular wavelength to passthrough, and the light is photoelectrically converted in each of the first pixel and the second pixel,
wherein a size of the opening for one of the first pixel or the second pixel having a relatively low light sensitivity is larger than a size of the opening for the other of the first pixel or the second pixel.

19. The photodetector according to claim 18, wherein the frame body includes a material having a refractive index lower than a refractive index of the color filter.

20. The photodetector according to claim 18, wherein
the materials include a first material and a second material, the first material provided as a common layer for the plurality of first pixels and the plurality of second pixels, and the second material provided for each first pixel of the first plurality of first pixels and for each second pixel of the plurality of second pixels, and t
he second material has a columnar structure having a size equal to or less than a predetermined wavelength of the incident light and has a refractive index higher than the first material.
